(19) United States
(12) Patent Application Publication
(10) Pub. No.: US 2026/0181916 A1
(43) Pub. Date: Jun. 25, 2026

(54) SEMICONDUCTOR MEMORY DEVICE

(71) Applicant: Kioxia Corporation, Tokyo (JP)

(72) Inventors: Masaki UNNO, Fujisawa Kanagawa (JP); Hiroshi MAEJIMA, Setagaya Tokyo (JP); Katsuaki ISOBE, Yokohama Kanagawa (JP); Takao NAKAJIMA, Yamato Kanagawa (JP); Nobuaki OKADA, Kawasaki Kanagawa (JP); Hiroyasu TANAKA, Yokohama Kanagawa (JP); Shigeki KOBAYASHI, Kamakura Kanagawa (JP); Hiroshi SHINOHARA, Yokosuka Kanagawa (JP)

(21) Appl. No.: 19/317,005

(22) Filed: Sep. 2, 2025

(30) Foreign Application Priority Data
Dec. 19, 2024 (JP) 2024-224178

(51) Int. Cl. H10B 80/00; G11C 16/26; H01L 23/00; H01L 25/065; H01L 25/18

(52) U.S. Cl. CPC H10B 80/00; G11C 16/26; H10W 90/00; H10W 90/792

(57) ABSTRACT

A semiconductor memory device includes first and second memory cell arrays, a first sense amplifier unit by which data is read from first and second memory cells of the first and second memory cell arrays, respectively, and a first switch circuit configured to switch between electrically connecting the first memory cells to the first sense amplifier unit, and electrically connecting the second memory cells to the first sense amplifier unit. The first memory cell array and the first sense amplifier unit overlap each other in a vertical direction; the second memory cell array is shifted in a horizontal direction with respect to the first memory cell array and the first sense amplifier unit; and the first switch circuit overlaps a region between the first and second memory cell arrays in the vertical direction or overlaps the first memory cell array in the vertical direction.

### CROSS-REFERENCE TO RELATED APPLICATION(S)

This application is based upon and claims the benefit of priority from Japanese Patent Application No. 2024-224178, filed Dec. 19, 2024, the entire contents of which are incorporated herein by reference.

### FIELD

Embodiments described herein relate generally to a semiconductor memory device.

### BACKGROUND

To increase the storage capacity of a semiconductor memory device, a structure including a plurality of memory cell arrays is considered. In such a structure, the number of sense amplifier units that read data from the memory cells is increased, and a wiring structure of bit lines for electrically connecting the sense amplifier units becomes more complex.

### BRIEF DESCRIPTION OF THE DRAWINGS

FIG. 1 is a block diagram of a semiconductor memory device according to an embodiment.

FIG. 2 is an equivalent circuit diagram showing an example of a configuration of a memory cell array provided in the semiconductor memory device according to the embodiment.

FIG. 3 is a circuit diagram showing an example of configurations of a sense amplifier unit and a latch circuit provided in the semiconductor memory device according to the embodiment.

FIG. 4 is a circuit diagram showing an example of a configuration of a row decoder provided in the semiconductor memory device according to the embodiment.

FIGS. 5A and 5B are schematic diagrams showing an overall configuration of the semiconductor memory device according to the embodiment.

FIGS. 6A and 6B are schematic diagrams illustrating a read operation and a write operation of the semiconductor memory device according to the embodiment.

FIGS. 7A to 7C are cross-sectional views showing an example of a configuration of the memory cell array and a peripheral circuit provided in the semiconductor memory device according to the embodiment.

FIGS. 8A and 8B are cross-sectional views showing an example of a configuration of a contact region and the peripheral circuit provided in the semiconductor memory device according to the embodiment.

FIGS. 9A to 9C are diagrams showing an example of a wiring structure electrically connecting the memory cell array and the sense amplifier unit according to the embodiment.

FIGS. 10A and 10B are enlarged plan views of a sub-bit line, a wiring, a bit line, and a relay wiring according to the embodiment.

FIGS. 11A and 11B are schematic diagrams illustrating a configuration and an operation of a semiconductor memory device according to a comparative example.

FIGS. 12A, 12B, and 13 are schematic diagrams illustrating a configuration of a semiconductor memory device according to Modification 1 of the embodiment.

FIGS. 14A and 14B are cross-sectional views showing an example of a configuration of a memory cell array and a peripheral circuit in a semiconductor memory device according to Modification 2 of the embodiment.

FIGS. 15A and 15B are cross-sectional views showing an example of a configuration of a memory cell array and a peripheral circuit in a semiconductor memory device according to Modification 3 of the embodiment.

FIGS. 16A and 16B are schematic diagrams showing a layout of the peripheral circuit provided in the semiconductor memory device according to Modification 3 of the embodiment.

FIGS. 17A to 17C are diagrams showing an example of a configuration of a semiconductor memory device according to Modification 4 of the embodiment.

FIG. 18 is a cross-sectional view showing an example of a configuration of a memory cell array and a peripheral circuit in the semiconductor memory device according to Modification 4 of the embodiment.

FIGS. 19A and 19B are diagrams illustrating a configuration of a semiconductor memory device according to Modification 5 of the embodiment.

FIG. 20 is a diagram illustrating a configuration of the semiconductor memory device according to Modification 5 of the embodiment.

### DETAILED DESCRIPTION

Embodiments provide a semiconductor memory device with a simple structure, that is capable of increasing storage capacity.

In general, according to one embodiment, a semiconductor memory device includes a first memory cell array including a plurality of first memory cells, a second memory cell array including a plurality of second memory cells, a first sense amplifier unit by which data is read from the plurality of first and second memory cells, and a first switch circuit that is configured to switch between electrically connecting the plurality of first memory cells to the first sense amplifier unit, and electrically connecting the plurality of second memory cells to the first sense amplifier unit. The first memory cell array and the first sense amplifier unit are arranged to overlap each other in a vertical direction; the second memory cell array is arranged at a position shifted in a horizontal direction with respect to the first memory cell array and the first sense amplifier unit; and the first switch circuit is arranged at a position overlapping a region between the first and second memory cell arrays in the vertical direction or a position overlapping the first memory cell array in the vertical direction.

Embodiments of the present disclosure will be described below with reference to the drawings. Note that the scope of the present disclosure is not limited to the following embodiments. The components in the following embodiments include those that can be readily conceived by a person skilled in the art or those that are substantially the same.

### Circuit Configuration of Semiconductor Memory Device

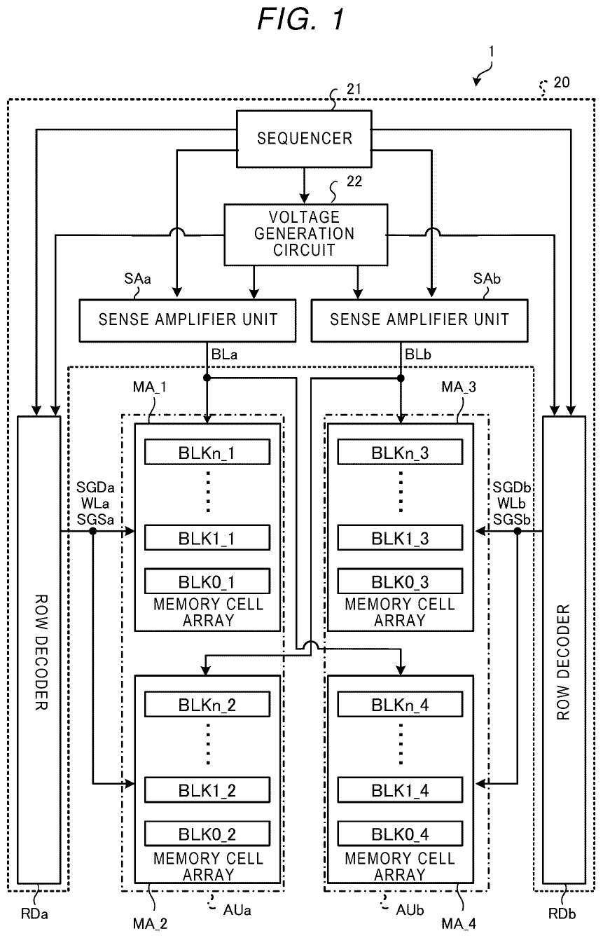

First, an example of a circuit configuration of a semiconductor memory device 1 of an embodiment will be described using FIGS. 1 to 4.

### Overall Configuration of Semiconductor Memory Device

FIG. 1 is a block diagram of the semiconductor memory device 1 according to the embodiment. Note that the connection modes of the respective components shown in FIG. 1 are merely examples, and the connections between components are not limited to those illustrated.

As shown in FIG. 1, the semiconductor memory device 1 includes a plurality of memory cell arrays MA (MA_1 to MA_4) and a peripheral circuit 20. Each of the plurality of memory cell arrays MA includes a plurality of memory cells. The peripheral circuit 20 controls th memory cells.

The memory cell array MA is a region in which nonvolatile memory cells are three-dimensionally arranged. In the example of FIG. 1, the semiconductor memory device 1 includes four memory cell arrays MA_1 to MA_4.

The peripheral circuit 20 includes a sequencer 21, a voltage generation circuit 22, a plurality of row decoders RD (RDa and RDb), and a plurality of sense amplifier units SA (SAa and SAb). In the example of FIG. 1, the semiconductor memory device 1 includes two row decoders RDa and RDb, and two sense amplifier units SAa and SAb.

The sequencer 21 is a circuit that controls the semiconductor memory device 1. The sequencer 21 controls the voltage generation circuit 22, the row decoders RDa and RDb, and the sense amplifier units SAa and SAb. The sequencer 21 also controls an overall operation of the semiconductor memory device 1 based on control by an external controller. More specifically, the sequencer 21 executes a write operation, a read operation, an erase operation, or the like.

The voltage generation circuit 22 is a circuit that generates voltages used for the write operation, the read operation, the erase operation, or the like. The voltage generation circuit 22 supplies voltages to the row decoders RDa and RDb, and the sense amplifier units SAa and SAb, or the like.

The row decoder RD is a circuit that decodes a row address. The row address is an address signal that specifies a wiring of the memory cell array MA in a row direction. The address signal is included in a write command, a read command, an erase command, or the like received from the external controller. The row decoder RD supplies a voltage from the voltage generation circuit 22 to the memory cell array MA based on a decoding result of the row address.

In the example of FIG. 1, one row decoder RD supplies the voltage to two memory cell arrays MA.

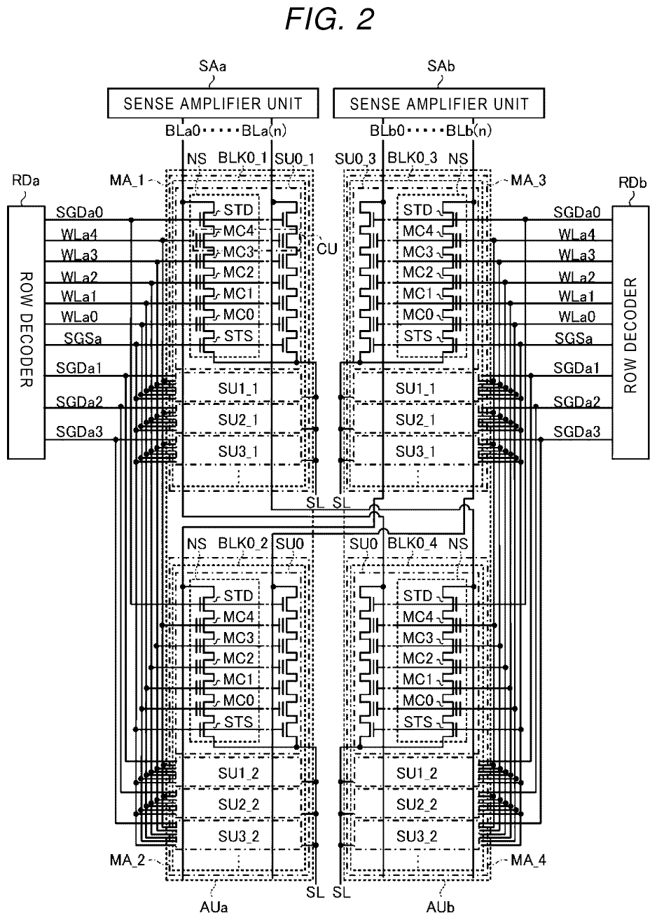

More specifically, the row decoder RDa is commonly connected to the memory cell arrays MA_1 and MA_2 via a plurality of word lines WLa and select gate lines SGDa and SGSa. Similarly, the row decoder RDb is commonly connected to the memory cell arrays MA_3 and MA_4 via a plurality of word lines WLb and select gate lines SGDb and SGSb. The word lines WLa and WLb are wirings used to control the memory cells. The select gate lines SGDa, SGDb, SGSa, and SGSb are wirings used to select a string unit SU (see FIG. 2) described later that includes a plurality of memory cells.

That is, the word line WLa of the memory cell array MA_1 and the word line WLa of the memory cell array MA_2 are commonly connected to the row decoder RDa. The select gate line SGDa of the memory cell array MA_1 and the select gate line SGDa of the memory cell array MA_2 are commonly connected to the row decoder RDa. The select gate line SGSa of the memory cell array MA_1 and the select gate line SGSa of the memory cell array MA_2 are commonly connected to the row decoder RDa. Thus, the word line WLa and the select gate lines SGDa and SGSa are shared by the memory cell array MA_1 and the memory cell array MA_2.

Similarly, the word line WLb of the memory cell array MA_3 and the word line WLb of the memory cell array MA_4 are commonly connected to the row decoder RDb. The select gate line SGDb of the memory cell array MA_3 and the select gate line SGDb of the memory cell array MA_4 are commonly connected to the row decoder RDb. The select gate line SGSb of the memory cell array MA_3 and the select gate line SGSb of the memory cell array MA_4 are commonly connected to the row decoder RDb. As a result, the word line WLb and the select gate lines SGDb and SGSb are shared by the memory cell array MA_3 and the memory cell array MA_4.

The sense amplifier unit SA is a circuit that writes and reads data. In the read operation, the sense amplifier unit SA senses data read from the corresponding memory cell array MA. In the write operation, the sense amplifier unit SA supplies a voltage according to write data to the corresponding memory cell array MA,.

In the example of FIG. 1, one sense amplifier unit SA supplies the voltage to two memory cell arrays MA.

More specifically, the sense amplifier unit SAa is commonly connected to the memory cell arrays MA_1 and MA_4 via a plurality of bit lines BLa. The sense amplifier unit SAb is commonly connected to the memory cell arrays MA_2 and MA_3 via a plurality of bit lines BLb.

That is, the bit line BLa of the memory cell array MA_1 and the bit line BLa of the memory cell array MA_4 are commonly connected to the sense amplifier unit SAa. The bit line BLb of the memory cell array MA_2 and the bit line BLb of the memory cell array MA_3 are commonly connected to the sense amplifier unit SAb. Thus, the bit line BLa is shared by the memory cell array MA_1 and the memory cell array MA_4. The bit line BLb is shared by the memory cell array MA_2 and the memory cell array MA_3.

Note that a switch circuit described later is provided between the bit line BLa of the memory cell array MA_1 and the bit line BLa of the memory cell array MA_4, and the sense amplifier unit SAa, and is configured to be able to switch connection between the memory cell array MA_1 and the sense amplifier unit SAa, or between the memory cell array MA_4 and the sense amplifier unit SAa. Similarly, a switch circuit described later is provided between the bit line BLb of the memory cell array MA_2 and the bit line BLb of the memory cell array MA_3, and the sense amplifier unit SAb, and is configured to be able to switch connection between the memory cell array MA_2 and the sense amplifier unit SAb, or between the memory cell array MA_3 and the sense amplifier unit SAb.

As described above, the memory cell arrays MA_1 and MA-2 connected to the common row decoder RDa via the common word line WLa and the select gate lines SGDa and SGSa, and connected to different sense amplifier units SAa and SAb via different bit lines BLa and BLb, respectively, form one array unit AUa. Similarly, the memory cell arrays MA-3 and MA-4 connected to the common row decoder RDb via a common word line WLb and the select gate lines SGDb and SGSb, and connected to different sense amplifier units SAb and SAa via different bit lines BLb and BLa, respectively, form one array unit AUb.

The memory cell array MA includes a plurality of blocks BLK. The block BLK is, for example, a set including a plurality of memory cells from which data is collectively erased. The plurality of memory cells in the block BLK correspond to rows and columns. In the example of FIG. 1, the memory cell array MA_1 includes BLK0_1, BLK1_1, . . . , and BLKn_1. The memory cell array MA_2 includes BLK0_2, BLK1_2, . . . , and BLKn_2. The memory cell array MA_3 includes BLK0_3, BLK1_3, . . . , and BLKn_3. The memory cell array MA_4 includes BLK0_4, BLK1_4, . . . , and BLKn_4.

The number of blocks BLK in the memory cell array MA is freely selected.

### Circuit Configuration of Memory Cell Array

FIG. 2 is an equivalent circuit diagram showing an example of a configuration of the memory cell arrays MA_1 to MA_4 in the semiconductor memory device 1 according to the embodiment.

As shown in FIG. 2, the block BLK includes a plurality of string units SU. The string unit SU is a set including a plurality of NAND strings NS that are selected collectively, for example, in the write operation or the read operation. The NAND string NS is a set including a plurality of memory cells MC connected in series.

In the example of FIG. 2, for example, the block BLK0_1 includes four string units SU0_1, SU1_1, SU2_1, and SU3_1. The block BLK0_2 includes four string units SU0_2, SU1_2, SU2_2, and SU3_2. The block BLK0_3 includes four string units SU0_3, SU1_3, SU2_3, and SU3_3. The block BLK0_4 includes four string units SU0_4, SU1_4, SU2_4, and SU3_4.

The NAND string NS includes a plurality of memory cells MC and select gates STD and STS. In the example of FIG. 2, the NAND string NS includes five memory cells MC0 to MC4.

The number of string units SU in the block BLK, the number of NAND strings NS in the string unit SU, and the number of memory cells MC in the NAND string NS are freely selected.

The memory cell MC stores data in a non-volatile manner. The memory cell MC includes a control gate and a charge storage layer. The memory cell MC may be a metal-oxide-nitride-oxide-silicon (MONOS) type or a floating gate (FG) type. The MONOS type uses an insulating layer as the charge storage layer. The FG type uses a conductive layer as the charge storage layer. In the following, a case in which the memory cell MC is of the MONOS type will be described.

The select gates STD and STS are used to select the string unit SU in various operations. The number of select gates STD and STS is freely selected as long as the NAND string NS includes at least one each.

The memory cells MC and the select gates STD and STS in the NAND string NS are connected in series. In the example of FIG. 2, the select gate STS, the memory cells MC0, MC1, MC2, MC3, and MC4, and the select gate STD are arranged sequentially from the bottom to the top of the drawing. Each of the NAND strings NS has a current path connected in series. In other words, the select gate STS, the memory cells MC0, MC1, MC2, MC3, and MC4, and the select gate STD are connected sequentially from a source line SL to the bit line BL. A drain of the select gate STD is connected to one of the bit lines BL. A source of the select gate STS is connected to the source line SL.

The drains of the plurality of select gates STD in the string unit SU are connected to different bit lines BL, respectively. In the example of FIG. 2, the drains of the select gates STD of n+1 (n is an integer equal to or greater than 0) NAND strings NS in the string unit SU are connected to n+1 bit lines BL, respectively. In each string unit SU of the two memory cell arrays MA, the drain of one select gate STD is commonly connected to one bit line BL. That is, the two memory cell arrays MA share the bit line BL.

More specifically, the n+1 select gates STD of the string units SU in the memory cell array MA_1 and the n+1 select gates STD of the string units SU in the memory cell array MA_4 are commonly connected to n+1 bit lines BLa0 to BLa(n), respectively. For example, the drain of one select gate STD of each of the string units SU0_1 to SU3_1 and the string units SU0_4 to SU3_4 is commonly connected to the bit line BLa0.

Similarly, the n+1 select gates STD of the string units SU in the memory cell array MA_2 and the n+1 select gates STD of the string units SU in the memory cell array MA_3 are commonly connected to n+1 bit lines BLb0 to BLb(n), respectively.

As described above, between each string unit SU of the memory cell array MA_1 and each string unit SU of the memory cell array MA_4, and the n+1 bit lines BLa0 to BLa(n), a switch circuit that switches connection to the memory cell array MA_1 side or the memory cell array MA_4 side is provided. Similarly, between each string unit SU of the memory cell array MA_2 and each string unit SU of the memory cell array MA_3, and the n+1 bit lines BLb0 to BLb(n), a switch circuit that switches connection to the memory cell array MA_2 side or the memory cell array MA_3 side is provided.

As described above, the memory cell arrays MA_1 and MA-2 form one array unit AUa, and the memory cell arrays MA-3 and MA-4 form one array unit AUb.

The control gates of the plurality of memory cells MC0 to MC4 in one block BLK of the memory cell array MA_1 and one block BLK of the memory cell array MA_2 are commonly connected to word lines WLa0 to WLa4, respectively.

More specifically, the blocks BLK0_1 and BLK0_2 include a plurality of memory cells MC0, and the control gates of the memory cells MC0 are commonly connected to one word line WLa0. Similarly, the rest of memory cells MC1 to MC4 are commonly connected to the word lines WLa1 to WLa4, respectively. In other words, the block BLK0_1 and the block BLK0_2 share the word line WL. The above configuration is similar for the rest of blocks BLK in the memory cell arrays MA_1 and MA_2.

Similarly, the control gates of the plurality of memory cells MC0 to MC4 in one block BLK in the memory cell array MA_3 and one block BLK in the memory cell array MA_4 are commonly connected to word lines WLb0 to WLb4, respectively.

More specifically, the blocks BLK0_3 and BLK0_4 include a plurality of memory cells MC0, and the control gates of the memory cells MC0 are commonly connected to one word line WLb0. Similarly, the rest of memory cells MC1 to MC4 are commonly connected to the word lines WLb1 to WLb4, respectively. In other words, the block BLK0_3 and the block BLK0_4 share the word line WL. The above configuration is similar for the rest of blocks BLK in the memory cell arrays MA_3 and MA_4.

A set including a plurality of memory cells MC connected to one word line WL in one string unit SU may be referred to as a cell unit CU. When the memory cell MC stores one bit of data, storage capacity of the cell unit CU is defined as “one page of data”. Based on the number of bits of data stored in the memory cell MC, the cell unit CU may have storage capacity of two or more pages of data.

Gates of the plurality of select gates STD in one string unit SU of one block BLK of the memory cell array MA_1 and one string unit SU of one block BLK of the memory cell array MA_2 are commonly connected to the select gate line SGDa.

For example, the string unit SU0_1 of the block BLK0_1 and the string unit SU0_2 of the block BLK0_2 each include a plurality of select gates STD, and the gates of the select gates STD are commonly connected to one select gate line SGDa0. That is, the string unit SU0_1 of the block BLK0_1 and the string unit SU0_2 of the block BLK0_2 share the select gate line SGDa0.

Similarly, the plurality of select gates STD in the string unit SU1_1 of the block BLK0_1 and the string unit SU1_2 of the block BLK0_2 are commonly connected to a select gate line SGDa1. The plurality of select gates STD in the string unit SU2_1 of the block BLK0_1 and the string unit SU2_2 of the block BLK0_2 are commonly connected to a select gate line SGDa2. The plurality of select gates STD in the string unit SU3_1 of the block BLK0_1 and the string unit SU3_2 of the block BLK0_2 are commonly connected to a select gate line SGDa3.

The above configuration is similar for the rest of blocks BLK of the memory cell arrays MA_1 and MA_2.

Gates of a plurality of select gates STD in one string unit SU of one block BLK of the memory cell array MA_3 and one string unit SU of one block BLK of the memory cell array MA_4 are commonly connected to the select gate line SGDb.

For example, the plurality of select gates STD in the string unit SU0_3 of the block BLK0_3 and the string unit SU0_4 of the block BLK0_4 are commonly connected to a select gate line SGDb0.

Similarly, the plurality of select gates STD in the string unit SU1_3 of the block BLK0_3 and the string unit SU1_4 of the block BLK0_4 are commonly connected to a select gate line SGDb1. The plurality of select gates STD in the string unit SU2_3 of the block BLK0_3 and the string unit SU2_4 of the block BLK0_4 are commonly connected to a select gate line SGDb2. The plurality of select gates STD in the string unit SU3_3 of the block BLK0_3 and the string unit SU3_4 of the block BLK0_4 are commonly connected to a select gate line SGDb3.

The above configuration is similar for the rest of blocks BLK of the memory cell arrays MA_3 and MA_4.

Gates of the plurality of select gates STS in one block BLK of the memory cell array MA_1 and in one block BLK of the memory cell array MA_2 are commonly connected to one select gate line SGSa.

More specifically, the blocks BLK0_1 and BLK0_2 include a plurality of select gates STS, and the gates of the select gates STS are commonly connected to one select gate line SGSa. In other words, the blocks BLK0_1 and BLK0_2 share the select gate line SGSa. The above configuration is similar for the rest of blocks BLK in the memory cell arrays MA_1 and MA_2.

In some embodiments, the memory cell arrays MA_1 and MA_2 may share a different select gate line SGSa for each string unit SU.

Gates of the plurality of select gates STS in one block BLK of the memory cell array MA_3 and in one block BLK of the memory cell array MA_4 are commonly connected to one select gate line SGSb.

More specifically, the blocks BLK0_3 and BLK0_4 include a plurality of select gates STS, and the gates of the select gates STS are commonly connected to one select gate line SGSb. In other words, the blocks BLK0_3 and BLK0_4 share the select gate line SGSb. The above configuration is similar for the rest of blocks BLK in the memory cell arrays MA_3 and MA_4.

In some embodiments, the memory cell arrays MA_3 and MA_4 may share a different select gate line SGSb for each string unit SU.

The source line SL is shared, for example, between the plurality of blocks BLK of the memory cell arrays MA_1 to MA_4.

### Circuit Configuration of Sense Amplifier Unit

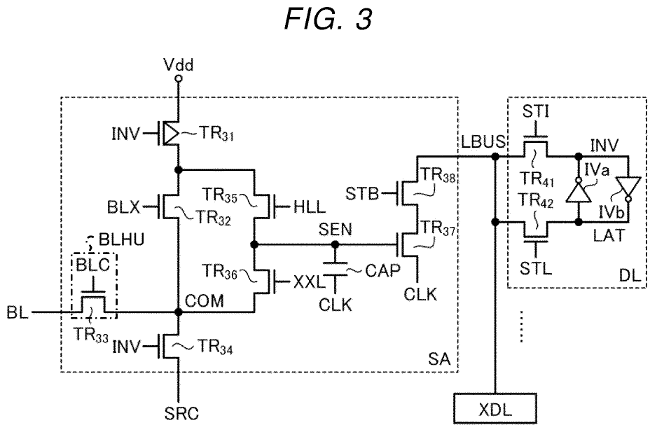

FIG. 3 is a circuit diagram showing an example of a configuration of the sense amplifier unit SA and latch circuits DL and XDL in the semiconductor memory device 1 according to the embodiment.

As described above, among the plurality of sense amplifier units SA, each sense amplifier unit SA provided for each bit line BL senses data read to the corresponding bit line BL in the read operation, for example, and determines whether the read data is “0” or “1”.

Each of the plurality of sense amplifier units is associated with a plurality of latch circuits DL. Among the latch circuits DL associated with the corresponding sense amplifier unit SA and the corresponding bit line BL, XDL is used for a cache operation of the semiconductor memory device 1. The number of latch circuits DL for one sense amplifier unit SA may correspond, for example, to the number of bits of data that can be stored by one memory cell MC.

FIG. 3 shows one sense amplifier unit SA and one of the latch circuits DL and XDL. A plurality of control signals supplied to the sense amplifier unit SA and the like are controlled by the sequencer 21.

As shown in FIG. 3, the sense amplifier unit SA includes transistors TR31 to TR38 and a capacitor CAP. In the drawing, the transistor TR31 is a low breakdown voltage p-channel metal-oxide-semiconductor (MOS) transistor. The transistors TR32 to TR38 are low breakdown voltage n-channel MOS transistors.

Low breakdown voltage CMOS transistors including the low breakdown voltage p-channel MOS transistors and the low breakdown voltage n-channel MOS transistors are transistors to which a relatively low voltage is applied, and are also called low voltage (LV) or very low voltage (VLV) MOS transistors.

One end of the transistor TR31 is connected to a power line to which a power supply voltage Vdd is supplied, and a gate electrode of the transistor TR31 is connected to a node INV. One end of the transistor TR₃₂ is connected to the other end of the transistor TR₃₁, the other end of the transistor TR₃₂ is connected to a node COM, and a control signal BLX is input to a gate electrode of the transistor TR₃₂.

A bit line connection circuit BLHU including the transistor TR₃₃ is a switch circuit that prevents a high voltage applied to a channel of the NAND string NS from being applied to the sense amplifier unit SA while erasing data in the memory cell MC. One end of the transistor TR₃₃ is connected to the node COM, the other end of the transistor TR₃₃ is connected to the corresponding bit line BL, and a control signal BLC is input to a gate electrode of the transistor TR₃₃.

One end of the transistor TR₃₄ is connected to the node COM, the other end of the transistor TR₃₄ is connected to a node SRC, and a gate electrode of the transistor TR₃₄ is connected to the node INV.

One end of the transistor TR₃₅ is connected to the other end of the transistor TR₃₁, the other end of the transistor TR₃₅ is connected to a node SEN, and a control signal HLL is input to a gate electrode of the transistor TR₃₅. One end of the transistor TR₃₆ is connected to the node SEN, the other end of the transistor TR₃₆ is connected to the node COM, and a control signal XXL is input to a gate electrode of the transistor TR_{36.}

A clock CLK is input to one end of the transistor TR₃₇, and a gate electrode of the transistor TR₃₇ is connected to the node SEN. One end of the transistor TR₃₈ is connected to the other end of the transistor TR₃₇, the other end of the transistor TR₃₈ is connected to a bus LBUS, and a control signal STB is input to a gate electrode of the transistor TR₃₈. One end of the capacitor CAP is connected to the node SEN, and the clock CLK is input to the other end of the capacitor CAP.

The latch circuit DL includes inverters IVa and IVb and transistors TR₄₁ and TR₄₂. In the drawing, the transistors TR₄₁ and TR₄₂ are low breakdown voltage N-channel MOS transistors. Although one latch circuit DL is shown in FIG. 3, the rest of latch circuits DL have the same configuration.

The inverter IVa is provided with an input terminal connected to a node LAT and an output terminal connected to the node INV. The inverter IVb is provided with an input terminal connected to the node INV and an output terminal connected to the node LAT.

The transistor TR₄₁ is provided with one end connected to the node INV and the other end connected to the bus LBUS, and a control signal STI is input to a gate electrode of the transistor TR₄₁. The transistor TR₄₂ is provided with one end connected to the node LAT and the other end connected to the bus LBUS, and a control signal STL is input to a gate electrode of the transistor TR₄₂.

The latch circuit XDL has a configuration substantially similar to that of the latch circuit DL, for example, and is connected to the bus LBUS to be able to transmit and receive data to and from the sense amplifier unit SA and the latch circuit DL. The latch circuit XDL is used for inputting and outputting data to and from the sense amplifier unit SA.

The latch circuit XDL is also used for a cache operation of the semiconductor memory device 1. That is, even when all the latch circuits DL corresponding to the sense amplifier unit SA are in use, when the latch circuit XDL is free, the semiconductor memory device 1 can receive data from outside.

Next, an operation of the sense amplifier unit SA configured as above will be briefly described.

As an example of writing data to the memory cell MC, when a charge is injected into the memory cell MC to raise a threshold, an “H” level (data of “1”) is stored at the node INV of the latch circuit DL. Thus, the transistor TR₃₄ is turned on, and the bit line BL is set to 0 V.

As another example of writing data to the memory cell MC, when a charge is not injected into the memory cell MC and the threshold is not changed, an “L” level (data of “0”) is stored at the node INV of the latch circuit DL. Thus, the transistor TR₃₁ is turned on, and a predetermined positive voltage is applied to the bit line BL.

In the read operation, the node INV is set to the “L” level and the transistor TR₃₁ is turned on. The bit line BL is pre-charged by the transistor TR₃₁ via the transistors TR₃₂ and TR₃₃. The transistor TR₃₅ is also turned on and the node SEN is charged to a predetermined voltage.

Thereafter, the transistor TR₃₅ is turned off, and the signal XXL is set to the “H” level so that the transistor TR₃₆ is turned on. As a result, when the corresponding memory cell MC is turned on with respect to the voltage applied to the word line, the voltage at the node SEN drops. Meanwhile, when the corresponding memory cell MC is turned off with respect to the voltage applied to the word line, the voltage at the node SEN remains at the “H” level. Therefore, the transistor TR37 turns off or on depending on whether the corresponding memory cell MC turns on or off with respect to the voltage applied to the word line.

By turning on the transistor TR₃₈ with the signal STB, a voltage according to an on/off state of the transistor TR₃₇ is read out to the bus LBUS and stored in the latch circuit DL.

Note that the circuit configuration of the sense amplifier unit SA and the latch circuits DL and XDL shown in FIG. 3 is merely an example, and the sense amplifier unit SA and the latch circuits DL and XDL may have various configurations other than those described above. Therefore, the number and types of transistors TR in each of the sense amplifier unit SA and the latch circuits DL and XDL may vary. For example, the sense amplifier unit SA and the latch circuits DL and XDL may be configured to include high breakdown voltage p-channel MOS transistors or high breakdown voltage n-channel MOS transistors.

### Circuit Configuration of Row Decoder

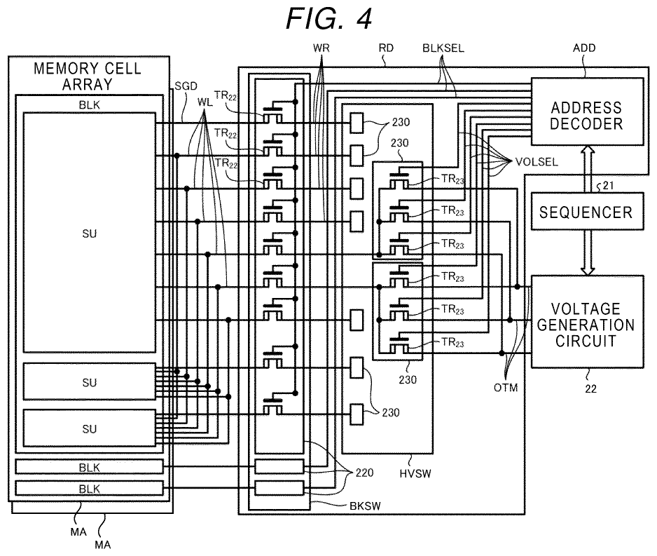

FIG. 4 is a circuit diagram showing an example of a configuration of the row decoder RD in the semiconductor memory device 1 according to the embodiment.

As shown in FIG. 4, the row decoder RD includes an address decoder ADD, a block selection circuit BKSW, and a voltage selection circuit HVSW.

The address decoder ADD includes a plurality of block selection lines BLKSEL and a plurality of voltage selection lines VOLSEL.

The address decoder ADD refers to address data in the latch circuit XDL described above, for example, according to a control signal from the sequencer 21.

The address decoder ADD decodes the referenced address data, turns on a transistor TR₂₂ and a transistor TR₂₃ corresponding to the address data, and turns off the other transistors TR₂₂ and TR₂₃. The transistor TR₂₂ and the transistor TR₂₃ are transistors provided in the block selection circuit BKSW and the voltage selection circuit HVSW described later, respectively.

The address decoder ADD sets voltages of the block selection line BLKSEL and the voltage selection line VOLSEL corresponding to the address data to, for example, an “H” state, and sets voltages of the rest of lines to an “L” state. Note that the voltages applied to the wirings are reversed depending on whether N-channel or P-channel transistors are used in the block selection circuit BKSW and the voltage selection circuit HVSW. The above voltages are provided as examples when the transistors are the N-channel type.

In the example of FIG. 4, the address decoder ADD is provided with one block selection line BLKSEL for each block BLK in the memory cell array MA. However, the configuration can be changed as appropriate. For example, one block selection line BLKSEL may be provided for two or more blocks BLK.

The block selection circuit BKSW includes a plurality of block selection units 220 each corresponding to the blocks BLK in the memory cell array MA. Each of the plurality of block selection units 220 includes a plurality of transistors TR₂₂ corresponding to the word lines WL and the select gate lines SGD and SGS.

The transistor TR₂₂ is a high breakdown voltage n-channel MOS transistor, and functions as a block drive transistor. A drain electrode of the transistor TR₂₂ is electrically connected to the corresponding word line WL or select gate line SGD or SGS. A source electrode of the transistor TR₂₂ is electrically connected to a voltage output terminal OTM via a wiring WR and the voltage selection circuit HVSW. Gate electrodes of the transistors TR₂₂ are commonly connected to the corresponding block selection lines BLKSEL.

The block selection circuit BKSW further includes a plurality of transistors (not shown) that are high breakdown voltage CMOS transistors connected between the select gate lines SGD and SGS and a ground voltage supply terminal. These plurality of transistors electrically connect the select gate lines SGD and SGS in non-selected blocks BLK in the memory cell array MA to the ground voltage supply terminal. The word lines WL in the non-selected blocks BLK are in a floating state.

The voltage selection circuit HVSW includes a plurality of voltage selection units 230 corresponding to the word lines WL and the select gate lines SGD and SGS. Each of the plurality of voltage selection units 230 includes a plurality of transistors TR_{23.}

The transistor TR₂₃ is a high breakdown voltage n-channel MOS transistor, and functions as a voltage select transistor. A drain terminal of the transistor TR₂₃ is electrically connected to the corresponding word line WL or select gate line SGD or SGS via the wiring WR and the block selection circuit BKSW. A source terminal is electrically connected to the corresponding voltage output terminal OTM. A gate electrode is connected to the corresponding voltage selection line VOLSEL.

High breakdown voltage CMOS transistors including high breakdown voltage p-channel MOS transistors and high breakdown voltage n-channel MOS transistors described above are transistors to which a relatively high voltage is applied, and are also called high voltage (HV) MOS transistors.

As such, the row decoder RD belonging to the peripheral circuit 20 includes the plurality of transistors TR₂₂ and TR₂₃, and the like. However, the circuit configuration of the row decoder RD shown in FIG. 4 is merely an example, and the number and types of the transistors TR₂₂ and TR₂₃, and the like in the row decoder RD may vary.

### Physical Configuration of Semiconductor Memory Device

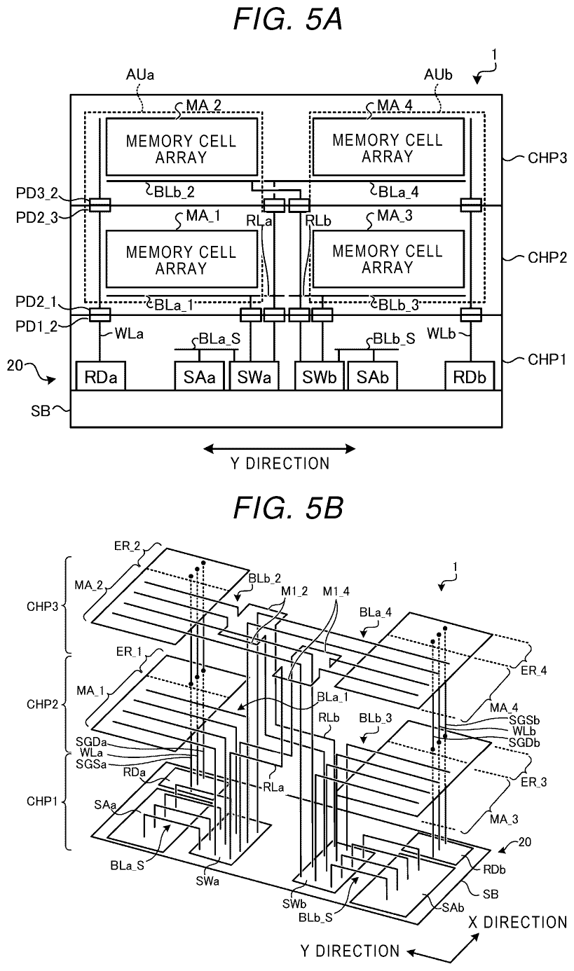

Next, an example of a physical configuration of the semiconductor memory device 1 of the embodiment will be described with reference to FIGS. 5A to 10B.

### Overall Configuration of Semiconductor Memory Device

FIGS. 5A and 5B are schematic diagrams showing an overview of an overall configuration of the semiconductor memory device 1 of the embodiment. More specifically, FIG. 5A is a layout diagram of the semiconductor memory device 1 as viewed from a Y direction, and FIG. 5B is a schematic perspective view of the semiconductor memory device 1.

In the specification, an X direction and the Y direction are both directions in a plane of the word line WL, and the X direction and the Y direction are perpendicular to each other. A direction in which the word lines WL are electrically routed may be referred to as a first direction, and the first direction is the X direction. A direction intersecting the first direction may be called a second direction, and the second direction is the Y direction. However, since the semiconductor memory device 1 may have manufacturing errors, the first direction and the second direction are not necessarily perpendicular to each other.

As shown in FIGS. 5A and 5B, the semiconductor memory device 1 has a configuration in which a circuit chip CHP1, an array chip CHP2, and an array chip CHP3 are stacked sequentially. In the specification, in the stacked structure of the circuit chip CHP1, the array chip CHP2, and the array chip CHP3, a side of the semiconductor memory device 1 on which the circuit chip CHP1 is disposed is referred to as a lower side of the semiconductor memory device 1.

The circuit chip CHP1 includes the peripheral circuit 20 including the sense amplifier units SAa and SAb, the row decoders RDa and RDb, and the like. The circuit chip CHP1 also includes switch circuits SWa and SWb that provide switch connection between the plurality of memory cell arrays MA_1 to MA_4 and the sense amplifier units SAa and SAb. The switch circuits SWa and SWb may be provided in the peripheral circuit 20.

The sense amplifier units SAa and SAb, the switch circuits SWa and SWb, and the row decoders RDa and RDb are disposed on a semiconductor substrate SB such as a silicon substrate provided on a side of the circuit chip CHP1 opposite to the array chip CHP2 side. More specifically, the sense amplifier unit SAa, the switch circuit SWa, the switch circuit SWb, and the sense amplifier unit SAb are disposed sequentially in the Y direction, for example, from a left side of the drawing.

As shown in FIG. 5B, the row decoder RDa is disposed side by side with the sense amplifier unit SAa in the X direction, and the row decoder RDb is disposed side by side with the sense amplifier unit SAb in the X direction.

As shown in FIGS. 5A and 5B, above the sense amplifier unit SAa, that is, on the array chip CHP2 side thereof, a sub-bit line BLa_S that connects the sense amplifier unit SAa to the switch circuit SWa is disposed. Above the sense amplifier unit SAb, that is, on the array chip CHP2 side thereof, a sub-bit line BLb_S that connects the sense amplifier unit SAb to the switch circuit SWb is disposed.

The array chip CHP2 is disposed above the circuit chip CHP1, and includes the memory cell arrays MA_1 and MA_3, and contact regions ER_1 and ER_3.

The memory cell arrays MA_1 and MA_3 are disposed side by side in the Y direction on the same layer, for example. The memory cell array MA_1 is located above the sense amplifier unit SAa, and the memory cell array MA_3 is located above the sense amplifier unit SAb.

The contact region ER_1 is a region associated with the memory cell array MA_1, disposed on at least one side of the memory cell array MA_1 in the Y direction, and provided with contacts connected to the word line WLa and the select gate lines SGDa and SGSa. The contact region ER_3 is a region associated with the memory cell array MA_3, disposed on at least one side of the memory cell array MA_3 in the X direction, and provided with contacts connected to the word line WLb and the select gate lines SGDb and SGSb.

A bit line BLa_1 connected to the plurality of memory cells MC in the memory cell array MA_1 is disposed below the memory cell array MA_1, that is, on the circuit chip CHP1 side thereof. A bit line BLb_3 connected to the plurality of memory cells MC in the memory cell array MA_3 is disposed below the memory cell array MA_3, that is, on the circuit chip CHP1 side thereof.

Relay wirings RLa and RLb are disposed between the memory cell arrays MA_1 and MA_3 that are aligned in the Y direction, and in the same layer as the bit lines BLa_1 and BLb_3. The relay wiring RLa is disposed closer to the bit line BLa_1, and the relay wiring RLb is disposed closer to the bit line BLb_3. The relay wiring RLa is located above the switch circuit SWa, and the relay wiring RLb is located above the switch circuit SWb.

The array chip CHP3 is disposed above the array chip CHP2, and includes the memory cell arrays MA_2 and MA_4 and contact regions ER_2 and ER_4.

The memory cell arrays MA_2 and MA_4 are disposed side by side in the Y direction on the same layer, for example. The memory cell array MA_2 is located above the sense amplifier unit SAa and the memory cell array MA_1, and the memory cell array MA_4 is located above the sense amplifier unit SAb and the memory cell array MA_3.

Thus, the memory cell arrays MA_1 and MA_2 disposed in a vertical direction across the two array chips CHP2 and CHP3 form one array unit AUa as described above. The memory cell arrays MA_3 and MA_4 disposed in the vertical direction across the two array chips CHP2 and CHP3 form one array unit AUb as described above.

The contact region ER_2 is a region associated with the memory cell array MA_2, disposed on at least one side of the memory cell array MA_2 in the X direction, and provided with contacts connected to the word line WLa and the select gate lines SGDa and SGSa. The contact region ER_4 is a region associated with the memory cell array MA_4, disposed on at least one side of the memory cell array MA_4 in the X direction, and provided with contacts connected to the word line WLb and the select gate lines SGDb and SGSb.

A bit line BLb_2 connected to the plurality of memory cells MC in the memory cell array MA_2 is disposed below the memory cell array MA_2, that is, above the memory cell array MA_1 of the array chip CHP2. A bit line BLa_4 connected to the plurality of memory cells MC in the memory cell array MA_4 is disposed below the memory cell array MA_4, that is, above the memory cell array MA_3 of the array chip CHP2.

Interfaces between the circuit chip CHP1 and the array chip CHP2 and between the array chip CHP2 and the array chip CHP3 are bonding surfaces at which the chips are bonded together, and the chips are provided with a plurality of wirings that extend between the plurality of chips. As shown in FIG. 5A, the wirings extend between the plurality of chips via a plurality of bonding pads PD1_2, PD2_1, PD2_3, and PD3_2.

The bonding pads PD1_2 are disposed on the circuit chip CHP1 side of the bonding surface between the circuit chip CHP1 and the array chip CHP2. The bonding pads PD2_1 are disposed on the array chip CHP2 side of the bonding surface between the circuit chip CHP1 and the array chip CHP2, and are connected to the bonding pads PD1_2 of the circuit chip CHP1, respectively.

The bonding pads PD2_3 are disposed on the array chip CHP2 side of the bonding surface between the array chip CHP2 and the array chip CHP3. The bonding pad PD3_2 are disposed on the array chip CHP3 side of the bonding surface between the array chip CHP2 and the array chip CHP3, and are connected to the bonding pads PD2_3 of the array chip CHP2, respectively.

As shown in FIGS. 5A and 5B, the plurality of memory cells MC and the select gates STD and STS in each of the memory cell arrays MA_1 and MA_2 are connected to the row decoder RDa via the word lines WLa, the select gate lines SGDa and SGSa, and the plurality of bonding pads PD1_2, PD2_1, PD2_3, and PD3_2. The plurality of memory cells MC and the select gates STD and STS in each of the memory cell arrays MA_3 and MA_4 are connected to the row decoder RDb via the word lines WLb, the select gate lines SGDb and SGSb, and the plurality of bonding pads PD1_2, PD2_1, PD2_3, and PD3_2.

The bit line BLa_1 connected to the memory cells MC of the memory cell array MA_1 is connected to the sense amplifier unit SAa via the bonding pads PD1_2 and PD2_1 and the switch circuit SWa. The bit line BLb_3 connected to the memory cells MC of the memory cell array MA_3 is connected to the sense amplifier unit SAb via the bonding pads PD1_2 and PD2_1 and the switch circuit SWb.

A part of the bit lines BLb_2 connected to the memory cells MC of the memory cell array MA_2 extends in the Y direction from below the memory cell array MA_2 to a region between the memory cell arrays MA_2 and MA_4, and are connected to the sense amplifier unit SAb via the bonding pads PD2_3 and PD3_2, the relay wiring RLb, the bonding pads PD1_2 and PD2_1, and the switch circuit SWb.

The rest of the bit lines BLb_2 connected to the memory cells MC of the memory cell array MA_2 are connected to the sense amplifier unit SAb via a wiring M1_2, the bonding pads PD2_3 and PD3_2, the relay wiring RLb, the bonding pads PD1_2 and PD2_1, and the switch circuit SWb, in which the wiring M1_2 extends in the Y direction from below the memory cell array MA_2 to the region between the memory cell arrays MA_2 and MA_4 in a layer below the bit lines BLb_2 and BLa_4 while avoiding the bit line BLa_4 of the memory cell array MA_4.

A part of the bit lines BLa_4 connected to the memory cells MC of the memory cell array MA_4 extends in the Y direction from below the memory cell array MA_4 to the region between the memory cell arrays MA_2 and MA_4, and is connected to the sense amplifier unit SAa via the bonding pads PD2_3 and PD3_2, the relay wiring RLa, the bonding pads PD1_2 and PD2_1, and the switch circuit SWa.

The rest of the bit lines BLa_4 connected to the memory cells MC of the memory cell array MA_4 are connected to the sense amplifier unit SAa via a wiring M1_4, the bonding pads PD2_3 and PD3_2, the relay wiring RLa, the bonding pads PD1_2 and PD2_1, and the switch circuit SWa, in which the wiring M1_4 extends in the Y direction from below the memory cell array MA_4 to the region between the memory cell arrays MA_2 and MA_4 in the layer below the bit lines BLa_4 and BLb_2 while avoiding the bit line BLb_2 of the memory cell array MA_2.

As such, the two memory cell arrays MA_1 and MA_3 in the array chip CHP2 are each connected to the sense amplifier unit SAa or SAb located below the array. Meanwhile, the two memory cell arrays MA_2 and MA_4 located on an upper layer of the memory cell arrays MA_1 and MA_3 and in the array chip CHP3 are connected to the sense amplifier unit SAb or SAa located below the other memory cell array MA_4 or MA_2, respectively.

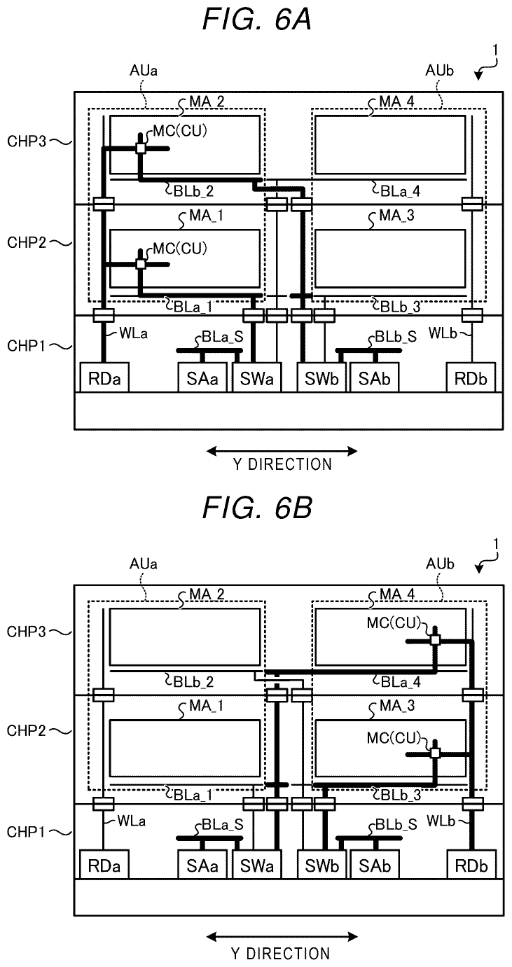

FIGS. 6A and 6B are schematic diagrams illustrating the read operation and the write operation of the semiconductor memory device 1 according to the embodiment. More specifically, FIG. 6A shows an example of the read operation or the write operation performed on the memory cells MC belonging to the array unit AUa. FIG. 6B shows an example of the read operation or the write operation performed on the memory cells MC belonging to the array unit AUb.

As shown in FIG. 6A, when the read operation or the write operation is performed on the memory cells MC belonging to the array unit AUa, a predetermined voltage is applied from the row decoder RDa to the select gate line SGDa corresponding to the target string unit SU among the plurality of string units SU in each of the memory cell arrays MA_1 and MA_2, and to the word line WLa corresponding to the operation target memory cell MC among the plurality of memory cells MC in the target string unit SU. Here, the operation target memory cell MC corresponds to a cell unit CU that includes a plurality of memory cells MC commonly connected to the corresponding word line WLa in the target string unit SU.

In other words, as described above, the cell units CU of the two memory cell arrays MA_1 and MA_2 are selected in parallel. As an example, referring to FIG. 2, when the row decoder RDa selects the word line WLa0 and the select gate line SGDa0, two cell units CU, that is, a cell unit CU including the plurality of memory cells MC0 of the string unit SU0_1 in the memory cell array MA_1 and a cell unit CU including the plurality of memory cells MC0 of the string unit SU0_2 in the memory cell array MA_2 are selected.

The switch circuit SWa connects the memory cell array MA_1 to the sense amplifier unit SAa, and a predetermined voltage is applied from the sense amplifier unit SAa to the plurality of memory cells MC in the cell unit CU of the memory cell array MA_1 via the sub-bit line BLa_S, the bit line BLa_1, and the like.

The switch circuit SWb connects the memory cell array MA_2 to the sense amplifier unit SAb, and a predetermined voltage is applied from the sense amplifier unit SAb to the plurality of memory cells MC in the cell unit CU of the memory cell array MA_2 via the sub-bit line BLb_S, the bit line BLb_2, and the like.

Thus, the read operation or the write operation is performed on the plurality of memory cells MC in the cell unit CU of each of the two memory cell arrays MA_1 and MA_2.

As shown in FIG. 6B, when the read operation or the write operation is performed on the memory cells MC belonging to the array unit AUb, a predetermined voltage is applied from the row decoder RDb to the select gate line SGDb corresponding to the target string unit SU among the plurality of string units SU in each of the memory cell arrays MA_3 and MA_4, and to the word line WLb corresponding to the cell unit CU that includes the operation target memory cells MC in the target string unit SU.

As described above, the cell units CU of the two memory cell arrays MA_3 and MA_4 are selected in parallel.

The switch circuit SWb connects the memory cell array MA_4 to the sense amplifier unit SAa, and a predetermined voltage is applied from the sense amplifier unit SAa to the plurality of memory cells MC in the cell unit CU of the memory cell array MA_4 via the sub-bit line BLa_S, the bit line BLa_4, and the like.

The switch circuit SWb connects the memory cell array MA_3 to the sense amplifier unit SAb, and a predetermined voltage is applied from the sense amplifier unit SAb to the plurality of memory cells MC in the cell unit CU of the memory cell array MA_3 via the sub-bit line BLb_S, the bit line BLb_3, and the like.

Thus, the read operation or the write operation is performed on the plurality of memory cells MC in the cell unit CU of each of the two memory cell arrays MA_3 and MA_4.

As described above, two memory cell arrays MA in each of the array units AUa and AUb are units of parallel processing capable of performing parallel processing, and the array units AUa and AUb are also called planes. Two memory cell arrays MA_1 and MA_3 in the same array chip CHP2 or two memory cell arrays MA_2 and MA_4 in the same array chip CHP2 is called a physical plane, and the array units AUa and AUb may be called logical planes for distinguishing with the physical planes.

### Configuration Example of Memory Cell Array

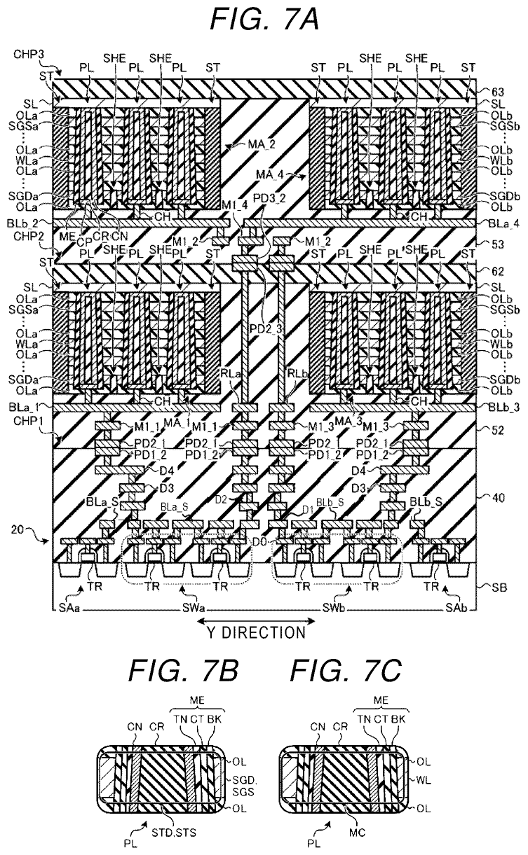

FIGS. 7A to 7C are cross-sectional views showing an example of a configuration of the memory cell array MA and the peripheral circuit 20 provided in the semiconductor memory device 1 according to the embodiment.

More specifically, FIG. 7A is a cross-sectional view of the memory cell array MA and the peripheral circuit 20 taken along the X direction. FIGS. 7B and 7C are enlarged cross-sectional views of a pillar PL in the memory cell array MA, in which FIG. 7B is an enlarged cross-sectional view of the pillar PL at a height of the select gate lines SGD and SGS, and FIG. 7C is an enlarged cross-sectional view of the pillar PL at a height of the word line WL.

As shown in FIG. 7A, each of the memory cell arrays MA_1 and MA_2 has a structure in which insulating layers 62 and 63 are used as bases, respectively, and a plurality of word lines WLa and a plurality of insulating layers OLa are stacked alternately one by one via the source line SL. One or more layers of the select gate lines SGSa are stacked above the uppermost word line WLa via the insulating layer OLa. One or more layers of the select gate lines SGDa are stacked below the lowermost word line WLa via the insulating layer OLa.

The word lines WLa and the select gate lines SGDa and SGSa connecting the memory cell arrays MA_1 and MA_2 to the row decoders RDa and RDb are referred to as global word lines and global select gate lines, respectively. To distinguish from the global lines, the word lines WLa and the select gate lines SGDa and SGSa in the memory cell arrays MA_1 and MA_2 may be referred to as local word lines and local select gate lines, respectively.

Each of the memory cell arrays MA_3 and MA_4 has a structure in which the insulating layers 62 and 63 are used as bases, respectively, and a plurality of word lines WLb and a plurality of insulating layers OLb are stacked alternately one by one via the source line SL. One or more layers of the select gate lines SGSb are stacked above the uppermost word line WLb via the insulating layer OLb. One or more layers of the select gate lines SGDb are stacked below the lowermost word line WLb via the insulating layer OLb.

The word lines WLa and WLb and the select gate lines SGDa, SGDb, SGSa, and SGSb connecting the memory cell arrays MA_1 to MA_4 to the row decoders RDa and RDb are referred to as global word lines and global select gate lines, respectively. To distinguish from the global lines, the word lines WLa and WLb and the select gate lines SGDa, SGDb, SGSa, and SGSb in the memory cell arrays MA_1 to MA_4 may be referred to as local word lines and local select gate lines, respectively.

The word lines WLa and WLb and the select gate lines SGDa, SGDb, SGSa, and SGSb are, for example, tungsten layers or molybdenum layers. The insulating layers OLa and OLb are, for example, silicon oxide layers. The source line SL is, for example, a polysilicon layer.

In the memory cell arrays MA_1 and MA_3, a stacked structure of the word lines WLa and WLb, and the like is covered with an insulating layer 52, and in the memory cell arrays MA_2 and MA_4, a stacked structure of the word lines WLa and WLb, and the like is covered with an insulating layer 53.

The memory cell arrays MA_1 to MA_4 are provided with a plurality of layers including a layer in which the stacked structure of the word lines WLa and WLb, and the like is disposed.

More specifically, the memory cell array MA_1 is provided with layers in which the source line SL, the stacked structure of the word line WLa and the like, the bit line BLa_1, a wiring M1_1, and the bonding pad PD2_1 are disposed sequentially downward from a layer in which the insulating layer 62 including the bonding pad PD2_3 is disposed, respectively. Here, the bonding pad PD2_3, the bit line BLa_1, the wiring M1_1, and the bonding pad PD2_1 are connected in the vertical direction to wiring layers by plugs.

The memory cell array MA_2 is provided with layers in which the source line SL, the stacked structure of the word line WLa and the like, the bit line BLb_2, the wiring M1_2, and the bonding pad PD3_2 are disposed sequentially downward from a layer in which the insulating layer 63 as a base is disposed, respectively. Here, the bit line BLb_2, the wiring M1_2, and the bonding pad PD3_2 are connected in the vertical direction to wiring layers by plugs.

The memory cell array MA_3 is provided with layers in which the source line SL, the stacked structure of the word line WLa and the like, the bit line BLb_3, a wiring M1_3, and the bonding pad PD2_1 are disposed sequentially downward from a layer in which the insulating layer 62 including the bonding pad PD2_3 is disposed, respectively. Here, the bonding pad PD2_3, the bit line BLb_3, the wiring M1_3, and the bonding pad PD2_1 are connected in the vertical direction to wiring layers by plugs.

The memory cell arrays MA_1 and MA_3 in the same array chip CHP2 share the insulating layer 62 as a base, and in the memory cell arrays MA_1 and MA_3, the source lines SL all belong to the same layer, the bonding pads PD2_3 in the insulating layer 62 all belong to the same layer, and the bonding pads PD2_1 all belong to the same layer. In the memory cell arrays MA_1 and MA_3, the stacked structure of the word line WLa and the like, the stacked structure of the word line WLb and the like, the bit lines BLa_1 and BLb_3, and the wirings M1_1 and M1_3 all belong to the same layer.

The relay wirings RLb and RLa that relay the bit lines BLb_2 and BLa_4 of the memory cell arrays MA_2 and MA_4 in the upper layer and connect to the switch circuits SWb and SWa belong to the same layer as, for example, the bit lines BLa_1 and BLb_3. The relay wirings RLb and RLa are also connected in the vertical direction to wiring layers by plugs.

Of the above-described plurality of components, the stacked structure of the word lines WLa and WLb, and the like, the bit lines BLa_1 and BLb_3, the relay wirings RLb and RLa, the wirings M1_1 and M1_3, and the bonding pad PD2_1 are all disposed in the insulating layer 52.

The memory cell array MA_4 is provided with layers in which the source line SL, the stacked structure of the word line WLb and the like, the bit line BLa_4, the wiring M1_4, and the bonding pad PD3_2 are disposed sequentially downward from a layer in which the insulating layer 63 as a base is disposed, respectively. Here, the bit line BLa_4, the wiring M1_4, and the bonding pad PD3_2 are connected in the vertical direction to wiring layers by plugs.

The memory cell arrays MA_2 and MA_4 in the same array chip CHP3 share the insulating layer 63 as a base, and in the memory cell arrays MA_2 and MA_4, the source lines SL all belong to the same layer, and the bonding pads PD2_1 all belong to the same layer. In the memory cell arrays MA_2 and MA_4, the stacked structure of the word lines WLa and the like and the stacked structure of the word lines WLb and the like, the bit lines BLb_2 and BLa_4, and the wirings M1_2 and M1_4 all belong to the same layer.

Therefore, in connection paths from the memory cell arrays MA_2 and MA_4 to the respective sense amplifier units SAb and SAa, in a layer in which the wirings M1_2 and M1_4 are disposed and the connection paths intersect, as described above, the wirings M1_2 and M1_4 are routed to avoid each other. In FIG. 7A, in the region between the memory cell arrays MA_2 and MA_4, the wirings M1_2 are shown on both sides in the Y direction with the wiring M1_4 interposed therebetween, the wiring M1_4 being located on the connection path from the memory cell arrays MA_2 and MA_4 to the respective sense amplifier units SAb and SAa as an example of an aspect in which the wirings M1_2 and M1_4 are routed.

Of the above-described plurality of components, the stacked structure of the word lines WLa and WLb, and the like, the bit lines BLb_2 and BLa_4, the wirings M1_2 and M1_4, and the bonding pad PD3_2 are all disposed in the insulating layer 53.

The memory cell arrays MA_1 to MA_4 include a plurality of plate-shaped portions ST that divide the stacked structure of the word lines WLa and WLb, and the like in the Y direction. More specifically, the plate-shaped portions ST penetrate the stacked structure of the word lines WLa and WLb, and the like at positions spaced apart from each other in the Y direction, and extend in a direction along the X direction. The plate-shaped portions ST are, for example, an insulating layer such as a silicon oxide layer.

In the memory cell arrays MA_1 to MA_4, the select gate lines SGDa and SGDb between the plate-shaped portions ST adjacent in the Y direction are separated into a plurality of sections in the Y direction by separation layers SHE. More specifically, the separation layers SHE penetrate the select gate lines SGDa and SGDb at positions spaced apart from each other in the Y direction, and extend in the direction along the X direction. The separation layer SHE is, for example, an insulating layer such as a silicon oxide layer.

The memory cell arrays MA_1 to MA_4 include a plurality of pillars PL that penetrate the stacked structure of the word lines WLa and WLb, and the like and reach the source line SL.

The pillar PL includes a core layer CR as a core material of the pillar PL, a channel layer CN that covers a side surface and an upper end of the core layer CR, and a memory layer ME that covers a side surface of the channel layer CN from outside. Thus, the channel layer CN exposed at the upper end of the pillar PL is connected to the source line SL. The pillar PL also includes a cap layer CP that covers lower ends of the channel layer CN and the core layer CR.

In the memory cell arrays MA_1 and MA_3, the cap layer CP is connected to the bit lines BLa_1 and BLb_3, respectively, by plugs CH that extend downward in the insulating layer 52. In the memory cell arrays MA_2 and MA_4, the cap layer CP is connected to the bit lines BLb_2 and BLa_4, respectively, by plugs CH that extend downward in the insulating layer 53.

As shown in FIGS. 7B and 7C, the memory layer ME has a stacked structure in which a block insulating layer BK, a charge storage layer CT, and a tunnel insulating layer TN are stacked sequentially from an outer periphery side of the pillar PL.

The block insulating layer BK, the tunnel insulating layer TN, and the core layer CR are, for example, silicon oxide layers. The charge storage layer CT is, for example, a silicon nitride layer. The channel layer CN and the cap layer CP are, for example, semiconductor layers such as silicon layers.

With the above configuration, as shown in FIG. 7C, the memory cells MC are formed in each portion of the side surface of the pillar PL facing the word lines WL. Data is written to and read from the memory cells MC by applying a predetermined voltage from the word line WL.

As such, since the memory cells MC are formed at intersections of the pillars PL and the plurality of word lines WL, the semiconductor memory device 1 is configured as a three-dimensional nonvolatile memory in which the memory cells MC are three-dimensionally arranged in the memory cell array MA.

The select gate STD shown in FIG. 7B is formed in each portion where the side surface of the pillar PL faces the select gate line SGD below the word lines WL. The select gate STS is formed in each portion where the side surface of the pillar PL faces the select gate line SGS above the word lines WL.

By applying a predetermined voltage from the select gate lines SGD and SGS, respectively, the select gates STD and STS are turned on or off, and the memory cell MC of the pillar PL to which the select gates STD and STS belong can be set to a selected state or a non-selected state.

The pillar PL in which the plurality of memory cells MC and the select gates STD and STS are connected in series has a physical configuration equivalent to the above-described NAND string NS (see FIG. 2 and the like). Among the plurality of pillars PL of the memory cell array MA, the memory cells MC and the select gates STD and STS formed in the pillars PL located between adjacent plate-shaped portions ST in the Y direction belong to one block BLK (see FIG. 2 and the like). The memory cells MC and the select gates STD and STS formed in the pillar PL located in each section of the select gate line SGD separated in the Y direction by the separation layers SHE belong to one string unit SU (see FIG. 2 and the like).

As shown in FIG. 7A, the circuit chip CHP1 includes the semiconductor substrate SB, the peripheral circuit 20 including the sense amplifier units SAa and SAb, the row decoders RDa and RDb, and the like, and the switch circuits SWa and SWb. The peripheral circuit 20 including the sense amplifier units SAa and SAb and the row decoders RDa and RDb, and the like, and the switch circuits SWa and SWb, include the plurality of transistors TR disposed on the semiconductor substrate SB.

The sense amplifier units SAa and SAb, the row decoders RDa and RDb, the switch circuits SWa and SWb, and the like are covered with an insulating layer 40.

The circuit chip CHP1 is provided with a plurality of layers including a layer in which the sense amplifier units SAa and SAb, the row decoders RDa and RDb, the switch circuits SWa and SWb, and the like are disposed.

More specifically, the circuit chip CHP1 is provided with layers in which wirings D0, D1, D2, D3, and D4, and the bonding pad PD1_2 are disposed vertically sequentially from a layer in which the sense amplifier units SAa and SAb, the row decoders RDa and RDb, and the switch circuits SWa and SWb, and the like are disposed. The wirings D0, D1, D2, D3, and D4, and the bonding pad PD1_2 are connected in the vertical direction to the wiring layers by plugs.

Here, the wiring D0 is connected to each transistor TR disposed on the semiconductor substrate SB via plugs. The sense amplifier units SAa and SAb and the switch circuits SWa and SWb are connected to each other via one of the layers in which the wirings D1, D2, D3, and D4 are disposed.

The sub-bit lines BLa_S and BLb_S connected to the sense amplifier units SAa and SAb, respectively, belong to the same layer as one of the wirings D1, D2, D3, and D4. Note that it is preferable for the sub-bit lines BLa_S and BLb_S to be disposed in a layer separated from the sense amplifier units SAa and SAb, such as the same layer as the wiring D4. Accordingly, it is possible to prevent noise generation and the like due to interaction between the sense amplifier units SAa and SAb and the sub-bit lines BLa_S and BLb_S.

The semiconductor memory device 1 configured as above is manufactured, for example, as follows.

That is, a structure in which a plurality of sacrificial layers and a plurality of insulating layers OL are alternately stacked one by one is formed on a wafer via the insulating layers 62 and 63 and the source lines SL, the stacked structure is separated for each memory cell array MA, the pillars PL are formed, and then the sacrificial layers are replaced with tungsten layers or the like, thereby forming a structure in which the plurality of word lines WL, the select gate lines SGD and SGS, and the plurality of insulating layers OL are alternately stacked. Replacement of the sacrificial layer with the tungsten layer or the like is performed via slits that will become the plate-shaped portions ST.

The stacked structure of the word lines WL and the like is covered with the insulating layers 52 and 53, various wirings including the bit lines BL and the like are formed in the insulating layers 52 and 53, and then the wafer is diced into the array chips CHP2 and CHP3 each including two memory cell arrays MA. Each of the array chips CHP2 and CHP3 may be cut from the same wafer or from different wafers.

Meanwhile, on a wafer such as a silicon wafer different from the above wafer, the peripheral circuit 20 provided with a plurality of transistors is formed and covered with the insulating layer 40. After various wirings including the wirings D0 to D4 and the like are formed in the insulating layer 40, the insulating layer 40 covering the peripheral circuit 20 is bonded to the insulating layer 52 of the array chip CHP2. The insulating layer 62 of the array chip CHP2 and the insulating layer 53 of the array chip CHP3 are bonded to each other. Then, the circuit chip CHP1 is diced so that each chip CHP1 is bonded to the array chips CHP2 and CHP3, each of which includes two memory cell arrays MA.

By forming a plurality of pairs of bonding pads PD1_2, PD2_1, PD2_3, and PD3_2 in advance at required locations on the bonding surface between the insulating layer 40 and the insulating layer 52 and on the bonding surface between the insulating layer 62 and the insulating layer 53, a plurality of wirings extending between the plurality of chips can be formed by bonding the circuit chip CHP1, the array chip CHP2, and the array chip CHP3.

The semiconductor memory device 1 of the embodiment is manufactured as described above.

### Configuration Example of Contact Region

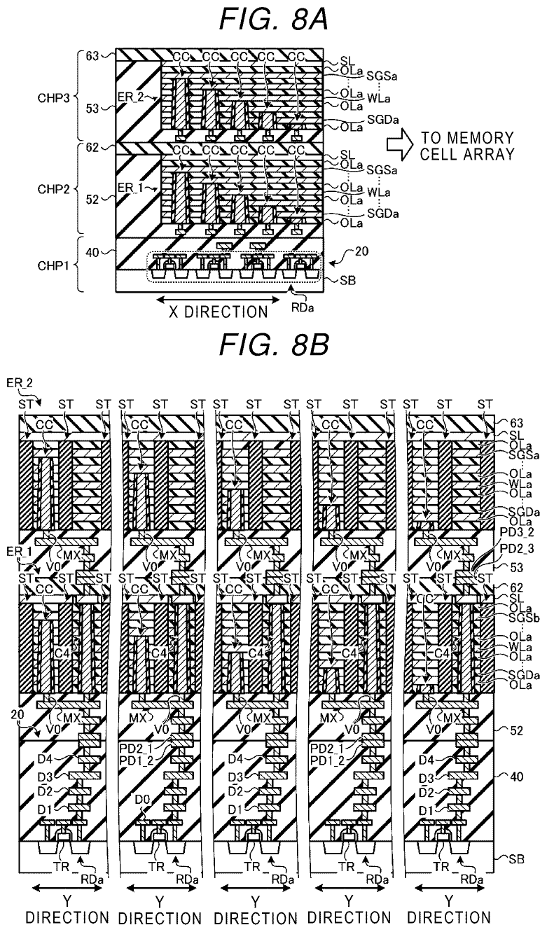

FIGS. 8A and 8B are cross-sectional views showing an example of a configuration of the contact region ER and the peripheral circuit 20 provided in the semiconductor memory device 1 according to the embodiment.

More specifically, FIG. 8A is a cross-sectional view of the contact region ER and the peripheral circuit 20 taken along the Y direction. FIG. 8B is a cross-sectional view at the position of each contact CC provided in the contact region ER in the Y direction, in which cross sections shown in FIG. 8B are located at different positions in the X direction.

In FIGS. 8A and 8B, the contact regions ER_1 and ER_2 each associated with the memory cell arrays MA_1 and MA_2 on one side of the semiconductor memory device 1 in the Y direction will be described as an example. Note that the contact regions ER_3 and ER_4 each associated with the memory cell arrays MA_3 and MA_4 on the other side in the Y direction also have the same configuration as the contact regions ER_1 and ER_2.

As shown in FIG. 8A, the word lines WLa, the select gate lines SGDa and SGSa, and the insulating layer OLa in the memory cell arrays MA_1 and MA_2 extend to the contact regions ER_1 and ER_2. A plurality of contacts CC are disposed in the contact regions ER_1 and ER_2.

The contacts CC extend upward to different depths in the stacked structure of the word lines WLa and the like, and are each connected to one of the plurality of word lines WLa and the select gate lines SGDa and SGSa. Here, the plurality of contacts CC, progressing from an X-direction end of the stacked structure of the word lines WLa on the left side of the drawing toward the memory cell arrays MA_1 and MA_2 on the right side of the drawing, are arranged so as to be connected to successive lower-layer word lines WLa.

In other words, the contact CC on the leftmost side of the drawing is connected to the select gate line SGSa, the contacts CC in the center of the drawing are connected to one of the word lines WLa, and the contact CC on the rightmost side of the drawing is connected to the select gate line SGDa.

In the circuit chip CHP1 below the array chips CHP2 and CHP3, for example, the row decoder RDa is disposed at a position overlapping the contact regions ER_1 and ER_2 in the vertical direction.

As shown in FIG. 8B, each of the contacts CC is connected to the lower row decoders RDa by a through contact C4 disposed in the adjacent block BLK separated by the plate-shaped portion ST.

More specifically, the contacts CC disposed in the contact region ER_2 are connected to an upper end of the through contact C4 via a plug V0, a wiring MX, the bonding pads PD3_2 and 2_3, and a conductive layer and the like disposed in the same layer as the source line SL, for example. The plug V0 is connected to the contact CC. The plug V0 in the contact region ER_2 belongs to the same layer as the above-described plug CH in the memory cell arrays MA_2 and MA_4, for example. The wiring MX connected to the contact CC via the plug V0 belongs to the same layer as the above-described wiring M1_2 and M1_4 in the memory cell arrays MA_2 and MA_4, for example.

The contact CC disposed in the contact region ER_1 is connected to a lower end of the through contact C4 via the plug V0 connected to the contact CC, the wiring MX, and the plug V0 connected to the through contact C4. The plugs V0 are connected to the contact CC and the through contact C4. The plugs V0 in the contact region ER_1 belong to the same layer as the above-described plug CH in the memory cell arrays MA_1 and MA_3, for example. The wirings MX connected to the contact CC and the through contact C4 via the plug V0 belong to the same layer as the above-described wirings M1_1 and M1_3 in the memory cell arrays MA_1 and MA_3, for example.

The through contact C4 is connected to the transistor TR of the row decoder RDa via the plug V0, the wiring MX, the bonding pads PD2_1 and PD1_2, the wiring D4 to D0, and the like.

As for the contacts CC connected to the select gate line SGDa, the same number of contacts CC as the number of sections of the select gate line SGDa separated by the separation layers SHE are disposed in one block BLK between the plate-shaped portions ST adjacent in the Y direction. However, in FIG. 8B, the separation layers SHE and the plurality of contacts CC for each section of the select gate line SGDa are omitted.

### Wiring Structure of Semiconductor Memory Device

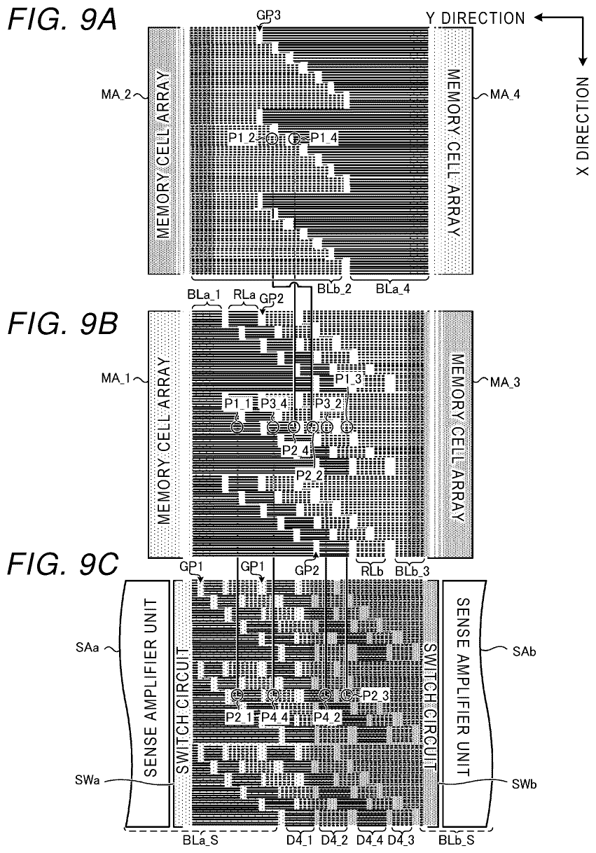

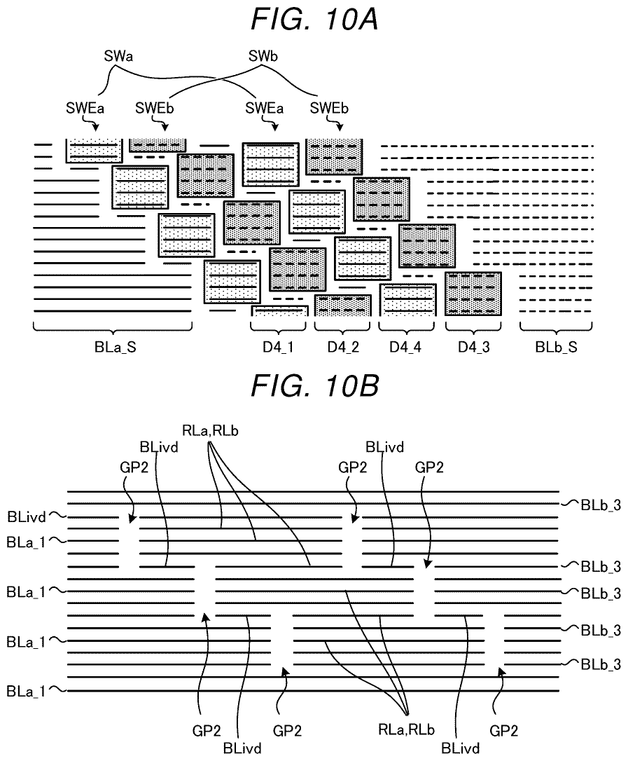

Next, a connection relationship between the memory cell array MA and the sense amplifier unit SA of the embodiment will be described in detail with reference to FIG. 9A to 10B.

FIGS. 9A to 9C are diagrams showing an example of a wiring structure that electrically connects the memory cell array MA and the sense amplifier unit SA of the embodiment.

More specifically, FIG. 9A is a plan view showing the bit lines BLb_2 and BLa_4 of the memory cell arrays MA_2 and MA_4. FIG. 9B is a plan view showing the relay wirings RLb and RLa that relay the bit lines BLa_1 and BLb_3 of the memory cell arrays MA_1 and MA_3 and the bit lines BLb_2 and BLa_4 of the memory cell arrays MA_2 and MA_4, respectively. FIG. 9C is a plan view showing the sub-bit lines BLa_S and BLb_S that connect the switch circuit SWa to the sense amplifier unit SAa, or the switch circuit SWb to the sense amplifier unit SAb.

In FIG. 9A, the memory cell arrays MA_2 and MA_4 disposed below the bit lines BLb_2 and BLa_4 are shown side by side sequentially from the left side of the drawing. In FIG. 9B, the memory cell arrays MA_1 and MA_3 disposed below the bit lines BLa_1 and BLb_3 are shown side by side sequentially from the left side of the drawing. In FIG. 9C, the sense amplifier units SAa and SAb disposed below the sub-bit lines BLa_S and BLb_S are shown on both the left and right sides of the drawing. Between the sense amplifier units SAa and SAb, for example, the switch circuit SWa and the switch circuit SWb are disposed sequentially from the left side of the drawing.

FIGS. 9A to 9C also show a connection relationship between the bit lines BLb_2, BLa_4, BLa_1, and BLb_3, the relay wirings RLa and RLb, and the sub-bit lines BLa_S and BLb_S.

As described above, the plurality of bit lines BLb_2 and the plurality of bit lines BLa_4 have approximately the same pitch between the wirings, and are disposed in positions overlapping each other in the X direction, respectively. Similarly, the plurality of bit lines BLa_1, the plurality of bit lines BLb_3, the plurality of relay wirings RLa, and the plurality of relay wirings RLb all have approximately the same pitch between the wirings, and are disposed in positions overlapping each other in the X direction, respectively. The plurality of sub-bit lines BLa_S and the plurality of sub-bit lines BLb_S also have approximately the same pitch between the wirings, and are disposed in positions overlapping each other in the X direction, respectively.

The plurality of bit lines BLb_2 and BLa_4, the plurality of bit lines BLa_1 and BLb_3, and the plurality of relay wirings RLa and RLb have approximately the same pitch between the wirings, and the plurality of bit lines BLb_2 and the plurality of relay wirings RLb, and the plurality of bit lines BLa_4 and the plurality of relay wirings RLa are disposed in positions overlapping each other in the vertical direction. The pitches between the wirings of the plurality of sub-bit lines BLa_S and BLb_S are also approximately the same as those of the bit lines BLb_2, BLa_4, BLa_1 and BLb_3, and the plurality of relay wirings RLa and RLb, and the plurality of sub-bit lines BLa_S and BLb_S are disposed in positions overlapping the plurality of bit lines BLa_1 and BLb_3, and the like in the vertical direction.

The bit lines BLb_2, BLa_4, BLa_1, and BLb_3, the relay wirings RLa and RLb, and the sub-bit lines BLa_S and BLb_S have pitches equal to or smaller than an exposure limit, for example, and are formed by a technique called a sidewall process. In the sidewall process, lines and spaces are formed with a pitch close to the exposure limit, sidewalls of the lines are covered with a wiring material, and the line portions are removed to obtain wirings of lines and spaces with a pitch approximately half the exposure limit.

Next, by cutting a part of the wiring to obtain the desired wiring pattern, the bit lines BLb_2, BLa_4, BLa_1 and BLb_3, the relay wirings RLa and RLb, the sub-bit lines BLa_S and BLb_S, and the like are formed. The wiring is finally formed into the desired pattern because it is difficult to form the wiring in the desired pattern from the beginning by the sidewall process equal to or lower than the exposure limit.

As shown in FIG. 9A, by cutting one portion of each wiring formed by the sidewall process in the Y direction to provide a gap GP3, the bit line BLb_2 extending from the memory cell array MA_2 side to the memory cell array MA_4 side and the bit line BLa_4 extending from the memory cell array MA_4 side to the memory cell array MA_2 side are formed.

Here, formation positions of the gaps GP3 are shifted in the Y direction for every predetermined number of wirings aligned in the X direction, and shift is repeated a predetermined number of times to obtain a plurality of sets with the same pattern including the bit lines BLb_2, some of which extend to positions overlapping the relay wiring RLb in the vertical direction, and the bit lines BLa_4, some of which extend to positions overlapping the relay wiring RLa in the vertical direction. Accordingly, connection between the bit lines BLb_2 and BLa_4 and the switch circuits SWb and SWa via the relay wirings RLb and RLa becomes easier.

In the example of FIG. 9A, shift of the formation positions of the gaps GP3 in the Y direction is repeated three times, and three sets of the bit lines BLb_2 and the three sets of the bit lines BLa_4 are formed with inverted patterns when viewed from above.

When the formation positions of the gaps GP3 are shifted for every predetermined number of wirings, it is preferable to form the gap GP3 by grouping a plurality of wirings together. Accordingly, it is possible to cut wirings with pitches equal to or lower than the exposure limit with good controllability.

As shown in FIG. 9B, in a layer of the bit lines BLa_1 and BLb_3 of the array chip CHP2, gaps GP2 are provided by repeating a plurality of times operations of shifting each wiring formed by the sidewall process in the Y direction for every predetermined number of wirings and cutting at three points in the Y direction, so that the bit line BLa_1, the relay wiring RLa, the relay wiring RLb, and the bit line BLb_3 are formed sequentially from the memory cell array MA_1 side to the memory cell array MA_3 side.

Accordingly, it is possible to obtain a plurality of sets including the relay wirings RLa and RLb with the same pattern overlapping the switch circuits SWa and SWb in the vertical direction. Accordingly, connection between the relay wirings RLa and RLb and the switch circuits SWa and SWb becomes easier.

In the example of FIG. 9B, shift in the Y direction of the formation positions of the gaps GP2 is repeated three times to form three sets including the relay wirings RLa and three sets including the relay wirings RLb having the same pattern.

As shown in FIG. 9C, even in a predetermined layer of the circuit chip CHP1, a position of a gap GP1 obtained by cutting each wiring formed by the sidewall process at five points in the Y direction for each predetermined number of wirings is shifted, so that a plurality of wirings D4 having the same pattern as the relay wirings RLa and RLb and the sub-bit lines BLa_S and BLb_S are formed.

In the example of FIG. 9C, for example, the gaps GP1 are provided for the wirings D4, and shift in the Y direction of the formation positions of the gaps GP1 is repeated three times.

Thus, three sets of the sub-bit lines BLa_S and three sets of the sub-bit lines BLb_S are formed on the left and right sides of the drawing with inverted patterns when viewed from the upper surface. As described above, the sub-bit lines BLa_S and BLb_S are disposed in positions overlapping the sense amplifier units SAa and SAb in the vertical direction, respectively.

Between the sub-bit lines BLa_S and BLb_S, three sets including wirings D4_1, D4_2, D4_4, and D4_3 are formed, the wirings having the same pattern to each other and being aligned sequentially from the sense amplifier unit SAa side to the sense amplifier unit SAb side. The wirings D4_1, D4_2, D4_4, and D4_3 are disposed in positions overlapping the bit line BLa_1, the relay wiring RLa, the relay wiring RLb, and the bit line BLb_3 in the vertical direction, respectively. Among the wirings D4_1, D4_2, D4_4, and D4_3, the wirings D4_1 and D4_4 are connected to the switch circuit SWa, and the wirings D4_2 and D4_3 are connected to the switch circuit SWb.

Accordingly, connection between the bit lines BLa_1 and BLb_3 and the switch circuits SWa and SWb via the wirings D4_1 and D4_3 becomes easier. Accordingly, connection between the bit lines BLb_2 and BLa_4 and the switch circuits SWb and SWa via the relay wirings RLb and RLa and the wirings D4_2 and D4_4 becomes easier.

The connection relationship between the bit lines BLb_2, BLa_4, BLa_1, and BLb_3 configured as described above and the sub-bit lines BLa_S and BLb_S will be described below.

As shown in FIGS. 9A to 9C, the connection path between the bit line BLa_1 and the sense amplifier unit SAa extends from a connection point P1_1 at a predetermined position on the bit line BLa_1 to a connection point P2_1 on the wiring D4_1 corresponding to the connection point P1_1. Thus, the bit line BLa_1 is connected to the switch circuit SWa, and is further connected to the sense amplifier unit SAa by the sub-bit line BLa_S.

The connection path between the bit line BLa_4 and the sense amplifier unit SAa extends from a connection point P1_4 at a predetermined position on the bit line BLa_4 to a connection point P2_4 on the relay wiring RLa corresponding to the connection point P1_4, a connection point P3_4 on the relay wiring RLa corresponding to the switch circuit SWa, and a connection point P4_4 on the wiring D4_4 corresponding to the connection point P3_4. Thus, the bit line BLa_4 is connected to the switch circuit SWa, and is further connected to the sense amplifier unit SAa by the sub-bit line BLa_S.

The connection path between the bit line BLb_3 and the sense amplifier unit SAb extends from a connection point P1_3 at a predetermined position on the bit line BLb_3 to a connection point P2_3 on the wiring D4_3 corresponding to the connection point P1_3. Thus, the bit line BLb_3 is connected to the switch circuit SWb, and is further connected to the sense amplifier unit SAb by the sub-bit line BLb_S.

The connection path between the bit line BLb_2 and the sense amplifier unit SAb extends from a connection point P1_2 at a predetermined position on the bit line BLb_2 to a connection point P2_2 on the relay wiring RLb corresponding to the connection point P1_2, and to a connection point P4_2 on the wiring D4_4 corresponding to the connection point P2_2. Thus, the bit line BLb_2 is connected to the switch circuit SWb, and is further connected to the sense amplifier unit SAb by the sub-bit line BLb_S.

An arrangement of the switch circuits SWa and SWb shown in FIG. 9C is schematic, and the switch circuits SWa and SWb can be disposed at any suitable locations for the above wiring structure.

As described above, when cutting a group of several wires formed by the sidewall process or the like, invalid wirings may be formed in the wiring portions.

FIGS. 10A and 10B are enlarged plan views of the sub-bit lines BLa_S and BLb_S, the wirings D4_1 to D4_4, the bit lines BLa_1 and BLb_3, and the relay wirings RLa and RLb according to the embodiment.

FIG. 10A shows the sub-bit lines BLa_S and BLb_S, the wirings D4_1 to D4_4, and the switch circuits SWa and SWb disposed below the lines and the wirings.

As shown in FIG. 10A, the switch circuit SWa may include a plurality of switch circuit elements SWEa disposed to overlap in the vertical direction with the wirings D4_1 and D4_4 shifting in the Y direction for each of a predetermined number of lines. Similarly, the switch circuit SWb may include a plurality of switch circuit elements SWEb disposed to overlap in the vertical direction with the wirings D4_2 and D4_3 shifting in the Y direction for each of a predetermined number of lines.

FIG. 10B shows invalid wirings BLivd of the bit lines BLa_1 and BLb_3 and the relay wirings RLa and RLb.

In the example shown in FIG. 10B, every four wirings aligned in the X direction are cut to form the gaps GP2. Here, two gaps GP2 adjacent in the XY direction are formed by targeting five wirings including one wiring in which both of the gaps GP2 are provided. Thus, even when the formation position of the gap GP2 is slightly shifted in the X direction or the width of the gap GP2 in the X direction varies, each of the narrow-pitch wirings can be cut more reliably at desired positions.

As described above, by providing two gaps GP2 adjacent in the XY direction for one wiring, both ends in the Y direction of a portion of the wiring located between the two gaps GP2 are cut, and the portion becomes, for example, the invalid wiring BLivd in a floating state.

As such, an unnecessary portion cut to form the desired pattern becomes the invalid wiring BLivd in a floating state, so that each wiring can be shortened to have only the required length, and parasitic capacitance of each wiring can be reduced.

The configurations of the sub-bit lines BLa_S and BLb_S, the wirings D4_1 to D4_4, the bit lines BLa_1 to BLa_4 and BLb_1 to BLb_4, and the relay wirings RLa and RLb are described above, but the above configuration is merely an example.

For example, the wirings are formed using the sidewall process or the like, but the embodiments are not limited thereto.

When using the sidewall process or the like, when sufficient controllability can be obtained while separating the wirings, the wirings may be cut individually one by one, rather than cutting the wirings in groups of a plurality of wirings.

When using the sidewall process or the like, the unnecessary wirings after separation may be left as the invalid wirings BLivd, but when sufficient controllability can be obtained, it is preferable that the invalid wirings BLivd are removed after or during separation.

Accordingly, it is possible to further reduce wiring capacitance. Alternatively, instead of simply making the separated wirings invalid, the wirings may be used as a shielding layer or the like to further reduce noise and capacitance.

When using the sidewall process or the like, when sufficient controllability can be obtained, the wirings may be formed to have a desired pattern from the beginning.

### SUMMARY

To increase storage capacity of the semiconductor memory device without increasing a chip area, a structure in which a plurality of memory cell arrays are stacked is being considered. Semiconductor memory devices 1x and 1y according to comparative examples having such a structure will be described below.

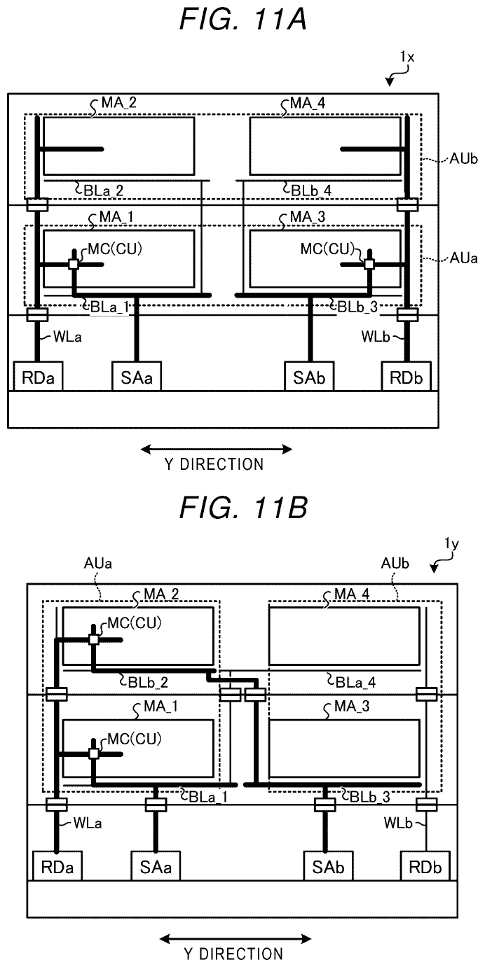

FIGS. 11A and 11B are schematic diagrams illustrating a configuration and an operation of the semiconductor memory devices 1x and 1y according to comparative examples.

The semiconductor memory device 1x according to the comparative example shown in FIG. 11A includes memory cell arrays MA_1 and MA_2, and memory cell arrays MA_3 and MA_4, that are disposed in positions overlapping each other in the vertical direction. The semiconductor memory device 1x according to the comparative example also includes sense amplifier units SAa and SAb and row decoders RDa and RDb below the memory cell arrays MA_1 to MA_4.

A bit line BLa_1 connected to the memory cell array MA_1 and a bit line BLa_2 connected to the memory cell array MA_2 are both connected to the sense amplifier unit SAa. The memory cell arrays MA_1 and MA_2 are connected to a row decoder RDa by a word line WLa.

A bit line BLb_3 connected to the memory cell array MA_3 and a bit line BLb_4 connected to the memory cell array MA_4 are both connected to the sense amplifier unit SAb. The memory cell arrays MA_3 and MA_4 are connected to a row decoder RDb by a word line WLb.

In the semiconductor memory device 1x having such a configuration, the memory cell arrays MA_1 and MA_3 belong to one array unit AUa, and are units of parallel processing capable of performing parallel processing. The memory cell arrays MA_2 and MA_4 belong to one array unit AUb, and are units of parallel processing capable of performing parallel processing.

As an example, when performing the read operation or the write operation on the array unit AUa, a predetermined voltage is applied to the word lines WLa and WLb, and the like corresponding to operation target memory cells MC, and a cell unit CU including a plurality of operation target memory cells MC is selected in the memory cell arrays MA_1 and MA_3. A predetermined voltage is applied from the sense amplifier units SAa and SAb to a plurality of memory cells MC in the cell unit CU of the memory cell arrays MA_1 and MA_3.

Thus, the read operation or the write operation is performed on the plurality of memory cells MC in the cell unit CU of each of the two memory cell arrays MA_1 and MA_3.

When a predetermined voltage is applied to the word lines WLa and WLb, and the like of the operation target memory cells MC in the memory cell arrays MA_1 and MA_3, the corresponding cell units CU are also selected in the memory cell arrays MA_2 and MA_4.

However, the memory cells MC of the cell units CU are not electrically connected to the sense amplifier units SAa and SAb. Accordingly, a voltage difference occurs between a channel layer of the memory cell MC and the word lines WLa and WLb to which a predetermined voltage is applied, thereby causing a parasitic capacitance, and it takes time to store charges for reading and writing data from and to the memory cell MC in the channel layer of the operation target memory cell MC in the memory cell arrays MA_1 and MA_3.

To solve the above problem, forming the memory cell arrays MA_1 and MA_2 and the memory cell arrays MA_3 and MA_4 that are commonly connected to the word line WLa or the word line WLb into array units AUa, AUb, respectively, may be considered. Accordingly, it is possible to reduce the number of memory cells MC that are in a selected state but are not electrically connected to the sense amplifier unit SA.

In the semiconductor memory device 1y according to the comparative example shown in FIG. 11B, a bit line BLa_1 connected to a memory cell array MA_1 and a bit line BLa_4 connected to a memory cell array MA_4 are connected to a sense amplifier unit SAa. A bit line BLb_2 connected to a memory cell array MA_2 and a bit line BLb_3 connected to a memory cell array MA_3 are connected to a sense amplifier unit SAb.

The memory cell arrays MA_1 and MA_2 are connected to a row decoder RDa by a word line WLa, and the memory cell arrays MA_3 and MA_4 are connected to a row decoder RDb by a word line WLb.

Thus, the memory cell arrays MA_1 and MA_2 belong to one array unit AUa, and the memory cell arrays MA_2 and MA_3 belong to one array unit AUb.

In such a configuration, as an example, when performing the read operation or the write operation on the array unit AUa, a predetermined voltage is applied to the word line WLa corresponding to operation target memory cells MC, and a cell unit CU including a plurality of operation target memory cells MC is selected in the memory cell arrays MA_1 and MA_2. A predetermined voltage is applied from the sense amplifier units SAa and SAb to a plurality of memory cells MC in the cell unit CU of the memory cell arrays MA_1 and MA_2.

Thus, the read operation or the write operation is performed on the plurality of memory cells MC in the cell unit CU of each of the two memory cell arrays MA_1 and MA_2.

However, a predetermined voltage is applied from the sense amplifier unit SAb to the memory cell array MA_2 via, for example, the bit line BLb_3 of the memory cell array MA_3. Therefore, a path for applying a voltage from the sense amplifier unit SAb to the memory cell array MA_2 is approximately twice as long as, for example, a path from the sense amplifier unit SAa to the memory cell array MA_1, thereby increasing parasitic capacitance and causing operational delays.

According to the semiconductor memory device 1 of the embodiment, the switch circuit SWb that switches connection between the sense amplifier unit SAb and the plurality of memory cells MC in each of the memory cell arrays MA_2 and MA_3 is provided. Accordingly, a predetermined voltage can be applied from the sense amplifier unit SAb to the memory cell array MA_2, for example, without passing the bit line BLb_3 of the memory cell array MA_3. Thus, it is possible to prevent an increase in parasitic capacitance and operational delays caused by extension of the length of the bit line BL.

According to the semiconductor memory device 1 of the embodiment, for example, four memory cell arrays MA can be operated with such a simple structure, and storage capacity of the semiconductor memory device 1 can be increased.

According to the semiconductor memory device 1 of the embodiment, the switch circuit SWb is disposed at a position overlapping the region between the memory cell arrays MA_2 and MA_3 in the vertical direction. Accordingly, connection between the memory cell array MA_2 and the switch circuit SWb becomes easier.

The semiconductor memory device 1 of the embodiment includes the plurality of sub-bit lines BLb_S extending in the Y direction and spaced apart from each other in the X direction at positions overlapping the plurality of bit lines BLb_3 in the vertical direction on the side of the sense amplifier unit SAb facing the memory cell array MA_3, and connected to the sense amplifier unit SAb. Accordingly, connection between the bit lines BLb_2 and BLb_3 of the memory cell arrays MA_2 and MA_3 and the sense amplifier unit SAb becomes easier.

The semiconductor memory device 1 of the embodiment further includes the sense amplifier unit SAa by which data is read from the plurality of memory cells MC in each of the memory cell arrays MA_1 and MA_4, and the switch circuit SWa that switches connection between the memory cells MC and the sense amplifier unit SAa. As such, by providing two sets of the sense amplifier units SAa and SAb and the switch circuits SWa and SWb, two memory cell arrays MA can be collectively processed as the array unit AU that is a unit of parallel processing.

The semiconductor memory device 1 of the embodiment includes the plurality of relay wirings RLb that extend in the Y direction at the same height as the plurality of bit lines BLb_2 of the memory cell array MA_2, at positions overlapping the plurality of bit lines BLb_2 in the X direction, between the memory cell arrays MA_2 and MA_3, and are connected to the switch circuit SWb. Accordingly, the memory cell array MA_2 and the switch circuit SWb are easily connected via the relay wirings RLb.

According to the semiconductor memory device 1 of the embodiment, at least a part of the plurality of bit lines BLb_2 are disposed at height positions between the plurality of bit lines BLb_2 and BLa_4 and the plurality of relay wirings RLa and RLb, and are connected to the plurality of relay wirings RLb via the plurality of wirings M1_2 that extend from positions overlapping the plurality of bit lines BLb_2 in the vertical direction to positions overlapping the plurality of relay wirings RLb in the vertical direction.

As such, the connection path between the memory cell array MA and the sense amplifier unit SA intersects the wiring M1_2 that belongs to a layer different from the bit line BLa_4, so that the memory cell arrays MA_2 and MA_4 can be connected to the sense amplifier units SAb and SAa, respectively, while avoiding interference between the bit lines BLb_2 and BLa_4.

### MODIFICATIONS

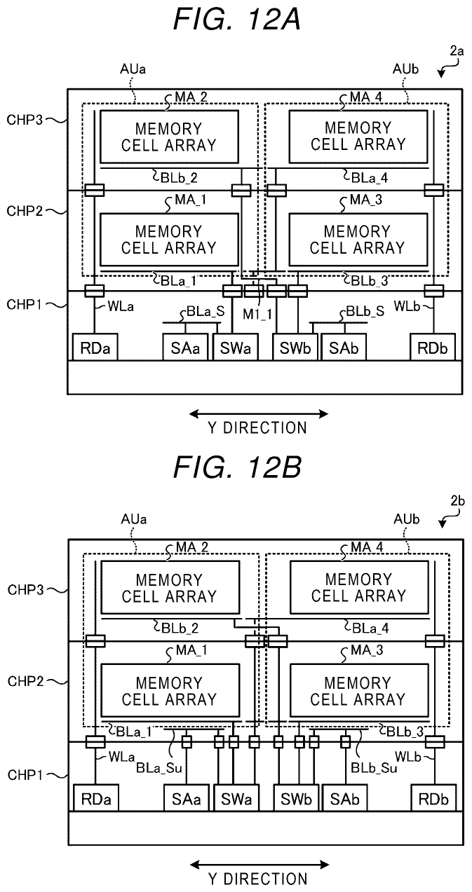

Next, semiconductor memory devices of various modifications of the embodiment will be described with reference to FIGS. 12A to 20. In the following description, the same reference numerals are used for configurations similar to those in the above-described embodiment, and description thereof may be omitted.

### Modification 1

FIGS. 12A to 13 are schematic diagrams illustrating configurations of semiconductor memory devices 2a to 2c according to Modification 1 of the embodiment. In the semiconductor memory devices 2a to 2c of Modification 1, wiring paths between the memory cell array MA and the sense amplifier unit SA are different from those in the above-described embodiment.

In the example shown in FIG. 12A, in the semiconductor memory device 2a of Modification 1, wiring paths between the memory cell arrays MA_2 and MA_4 and the sense amplifier units SAa and SAb intersect on the layer of the wirings M1_1 and M1_3 of the memory cell arrays MA_1 and MA_3 of the array chip CHP2, instead of intersecting on the layer of the wirings M1_2 and M1_4 of the memory cell arrays MA_2 and MA_4 of the array chip CHP3.

In the example shown in FIG. 12B, in the semiconductor memory device 2b of Modification 1, sub-bit lines BLa_Su and BLb_Su connecting the sense amplifier unit SA to the switch circuit SW are disposed on the array chip CHP2 side instead of on the circuit chip CHP1 side.

In other words, the sub-bit line BLa_Su connecting the sense amplifier unit SAa to the switch circuit SWa is disposed in the layer of the wiring M1_1 below the memory cell array MA_1. The sub-bit line BLb_Su connecting the sense amplifier unit SAb to the switch circuit SWb is disposed in the layer of the wiring M1_3 below the memory cell array MA_3.

In the example shown in FIG. 13, the semiconductor memory device 2c of Modification 1 is provided with the memory cell array MA_1 and the memory cell array MA_3 as one array unit AUa, and the memory cell array MA_2 and the memory cell array MA_4 as one array unit AUb. In other words, the array units AUa and AUb are disposed in the array chips CHP2 and CHP3, respectively, to match the logical plane with the physical plane.

More specifically, for example, the memory cell arrays MA_1 and MA_2 are connected to the sense amplifier unit SAa or the sense amplifier unit SAb via the switch circuit SWa or the switch circuit SWb, respectively, as in the above-described embodiment.

Meanwhile, the memory cell array MA_3 is connected to the sense amplifier unit SAa via the switch circuit SWa, unlike the above-described embodiment.

To connect the memory cell array MA_3 to the sense amplifier unit SAa, as shown in FIG. 13, a bit line BLa_3 of the memory cell array MA_3 is extended to a position overlapping the switch circuit SWa in the vertical direction in any of the layers in which the wirings D1 to D4 of the circuit chip CHP1 are disposed, and is connected to the switch circuit SWa and the sense amplifier unit SAa.

Alternatively, the connection path between the memory cell array MA_3 and the sense amplifier unit SAa may intersect, for example, in the layer of the wiring M1_3 of the array chip CHP2 instead of in any layer of the circuit chip CHP1.

The memory cell array MA_4 is connected to the sense amplifier unit SAb via the switch circuit SWb. Here, for example, the bit line BLb_4 of the memory cell array MA_4 is connected to the switch circuit SWb and the sense amplifier unit SAb via the relay wiring RLb disposed in the same layer as the bit lines BLa_1 and BLa_3 of the array chip CHP2.

According to the semiconductor memory device 2a of Modification 1, at least a part of the plurality of bit lines BLb_2 extend from a position overlapping the memory cell array MA_2 in the vertical direction to a position overlapping each of the plurality of relay wirings RLb in the vertical direction, and are connected to each of the plurality of relay wirings RLb. Even in such a configuration, the same effect as the above-described embodiment can be achieved.

According to the semiconductor memory device 2b of Modification 1, the plurality of sub-bit lines BLa_Su and BLb_Su are disposed on the memory cell array MA_1 and MA_3 side while sandwiching an interface including the bonding pads PD2_1 and PD1_2 between the memory cell arrays MA_1 and MA_3 and the sense amplifier units SAa and SAb.

Accordingly, the sub-bit lines BLa_Su and BLb_Su are further separated from the sense amplifier units SAa and SAb, and interaction with the sense amplifier units SAa and SAb can be further prevented, thereby reducing noise.

According to the semiconductor memory device 2b of Modification 1, other effects similar to those of the above-described embodiment are achieved.

According to the semiconductor memory device 2c of Modification 1, the plurality of memory cells MC of the memory cell arrays MA_1 and MA_3 are connected to the switch circuit SWa via the plurality of relay wirings RLa, and the plurality of memory cells MC of the memory cell arrays MA_2 and MA_4 are connected to the switch circuit SWb via the relay wirings RLb. Even in such a configuration, the same effect as the above-described embodiment can be achieved.

### Modification 2

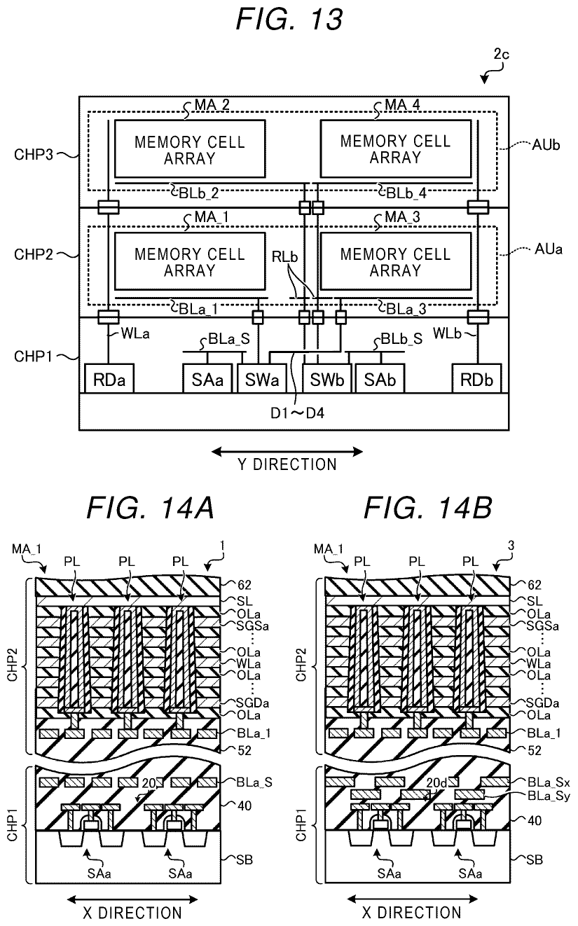

FIGS. 14A and 14B are cross-sectional views taken along the Y direction showing an example of a configuration of a memory cell array MA_1 and a peripheral circuit 20d provided in a semiconductor memory device 3 according to Modification 2 of the embodiment. The semiconductor memory device 3 of Modification 2 differs from the above-described embodiment in that the sub-bit lines BLa_S and BLb_S are disposed across a plurality of layers.

Note that, for comparison, FIG. 14A shows the configuration of the above-described embodiment, and FIG. 14B shows the configuration of Modification 2.

As shown in FIG. 14A, in the semiconductor memory device 1 of the embodiment, the sub-bit lines BLa_S have, for example, approximately the same pitches as the bit lines BLa_1 of the memory cell array MA_1, and are disposed in positions that overlap the bit lines BLa_1 in the vertical direction.

As shown in FIG. 14B, in the semiconductor memory device 3 of Modification 2, sub-bit lines BLa_Sx and BLa_Sy are disposed across a plurality of layers of the circuit chip CHP1. Here, the sub-bit line BLa_Sx and the sub-bit line BLa_Sy may each have a wider pitch and a wider wiring width than the bit line BLa_1 of the memory cell array MA_1.

According to the semiconductor memory device 3 of Modification 2, among the plurality of sub-bit lines BLa_Sx and BLa_Sy, the sub-bit line BLa_Sx is disposed between the plurality of bit lines BLa_1 and the sense amplifier unit SAa at a predetermined height position closer to the height position of the sense amplifier unit SAa than the height position of the plurality of bit lines BLa_1, and the sub-bit line BLa_Sy is disposed at a height position further closer to the height position of the sense amplifier unit SAa than the height position of the sub-bit line BLa_Sx.

Thus, by disposing the sub-bit lines BLa_Sx and BLa_Sy in a plurality of layers, the pitch and the wiring width of each of the sub-bit lines BLa_Sx and BLa_Sy can be increased. As a result, for example, in a process for the circuit chip CHP1, the sub-bit lines BLa_Sx and BLa_Sy can be formed without using the sidewall process or the like that requires precise control.

According to the semiconductor memory device 3 of Modification 2, other effects similar to those of the above-described embodiment are achieved.

### Modification 3

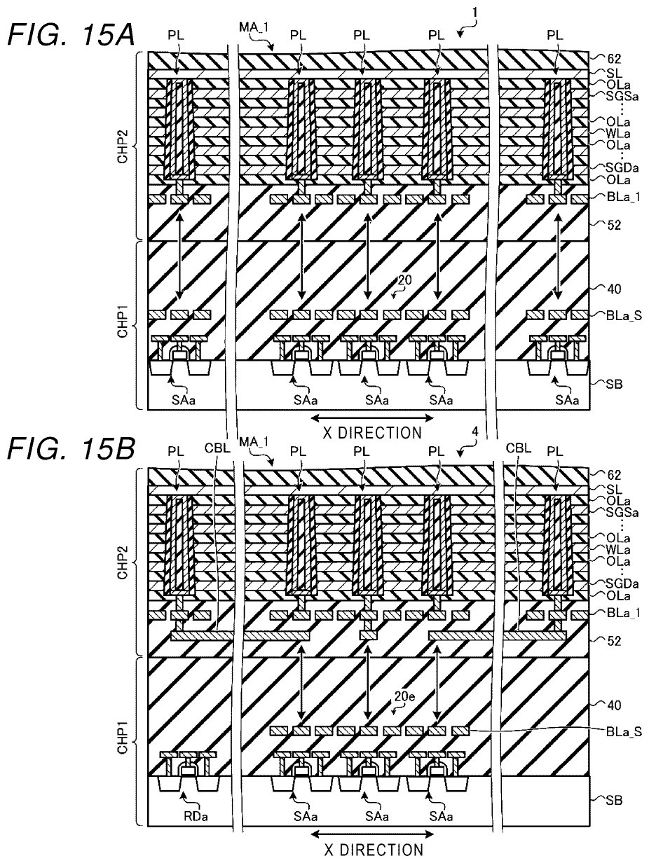

FIGS. 15A and 15B are cross-sectional views taken along the Y direction showing an example of a configuration of a memory cell array MA_1 and a peripheral circuit 20e provided in a semiconductor memory device 4 according to Modification 3 of the embodiment. The semiconductor memory device 4 of Modification 3 differs from the above-described embodiment in that sense amplifier units SA in the peripheral circuit 20e are concentrated at a predetermined position in the X direction.

Note that, for comparison, FIG. 15A shows the configuration of the above-described embodiment, and FIG. 15B shows the configuration of Modification 3.

As shown in FIG. 15A, in the semiconductor memory device 1 of the embodiment, the plurality of sense amplifier units SAa are disposed in positions that overlap in the vertical direction across, for example, the entire area of the memory cell array MA_1 in the X direction. The plurality of sub-bit lines BLa_S of each sense amplifier unit SAa are each disposed in the X direction in positions that overlap in the vertical direction with the plurality of bit lines BLa_1 of the memory cell array MA_1.

As shown in FIG. 15B, in the semiconductor memory device 4 of Modification 3, the plurality of sense amplifier units SAa are concentrated and disposed, for example, near a center of the region of memory cell array MA_1 in the X direction. Therefore, in positions away from the center in the X direction, regions in which the sense amplifier units SAa are not disposed below the memory cell array MA_1 may exist.

Accordingly, it is possible to dispose other components of the peripheral circuit 20e such as the row decoders RDa provided corresponding to the plurality of word lines WL and having a relatively large installation area on the semiconductor substrate SB, in the region in which the sense amplifier units SAa are not disposed below the memory cell array MA_1.

To connect the bit lines BLa_1 in a region in which the sense amplifier units SAa are not disposed to the sense amplifier units SAa near the center in the X direction, it is possible to use a relay wiring CBL that extends from a position that overlaps the bit lines BLa_1 in the vertical direction to a position that overlaps the sense amplifier units Saa in the vertical direction near the center in the X direction. The relay wiring CBL can be disposed, for example, in a layer in which the wiring M1_1 of the array chip CHP2 is disposed.

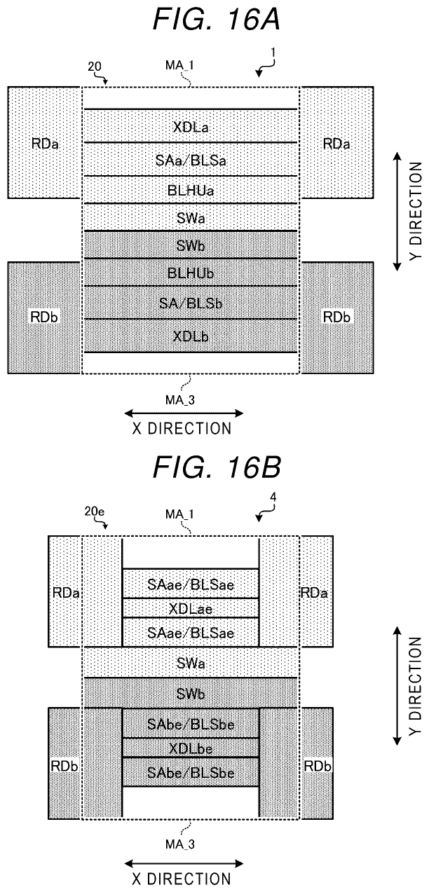

FIGS. 16A and 16B are schematic diagrams showing a layout of the peripheral circuit 20e provided in the semiconductor memory device 4 according to Modification 3 of the embodiment.

Note that, for comparison, FIG. 16A shows the configuration of the above-described embodiment, and FIG. 16B shows the configuration of Modification 3.

As shown in FIG. 16A, the peripheral circuit 20 is provided with the sense amplifier unit SAa associated with a bit line selection circuit BLSa, a bit line connection circuit BLHUa (see FIG. 3 and the like), a latch circuit XDLa, the switch circuit SWa, the row decoder RDa, and the like corresponding to the memory cell array MA_1. The bit line selection circuit BLSa is a circuit that selects the bit line BLa_1 corresponding to the operation target memory cell MC and electrically connects the selected bit line to the corresponding sense amplifier unit SAa.

Similarly to the above, the sense amplifier unit SAb associated with a bit line selection circuit BLSb, a bit line connection circuit BLHUb, a latch circuit XDLb, the switch circuit SWb, the row decoder RDb, and the like are provided corresponding to the memory cell array MA_3.

In the semiconductor memory device 1 of the embodiment, the sense amplifier units SAa and SAb, the bit line connection circuits BLHUa and BLHUb, the latch circuits XDLa and XDLb, and the switch circuits SWa and SWb are disposed across almost the entire region corresponding to the memory cell arrays MA_1 and MA_3. As such, widths in the X direction of the sense amplifier units SAa and SAb, the bit line connection circuits BLHUa and BLHUb, and the latch circuits XDLa and XDLb are approximately the same as widths in the X direction of the memory cell arrays MA_1 and MA_3.

The row decoders RDa and RDb are disposed, for example, outside in the X direction of the region corresponding to the memory cell arrays MA_1 and MA_3. The row decoders RDa and RDb may be disposed only on one side in the X direction of the memory cell arrays MA_1 and MA_3, as in the above example of FIG. 5B of the embodiment.

As shown in FIG. 16B, in the semiconductor memory device 4 of Modification 3, the peripheral circuit 20e includes sense amplifier units SAae and SAbe, bit line connection circuits BLHUae and BLHUbe, and latch circuits XDLae and XDLbe that are narrower in the X direction than the memory cell arrays MA_1 and MA_3. In the example of FIG. 16B, the sense amplifier units SAae and SAbe are disposed on both sides in the Y direction with each of the latch circuits XDLae and XDLbe interposed therebetween.

As such, by narrowing the widths in the X direction of the sense amplifier units SAae and SAbe, and the like, the row decoders RDa and RDb on both sides of the memory cell arrays MA_1 and MA_3 in the X direction can be disposed to overlap the memory cell arrays MA_1 and MA_3 partially in the vertical direction, thereby reducing a chip size.

The above-described configurations of the embodiment and various modifications can also be applied to the semiconductor memory device 4. Thus, according to the semiconductor memory device 4 of Modification 3, effects similar to those of the above-described embodiment are achieved.

### Modification 4

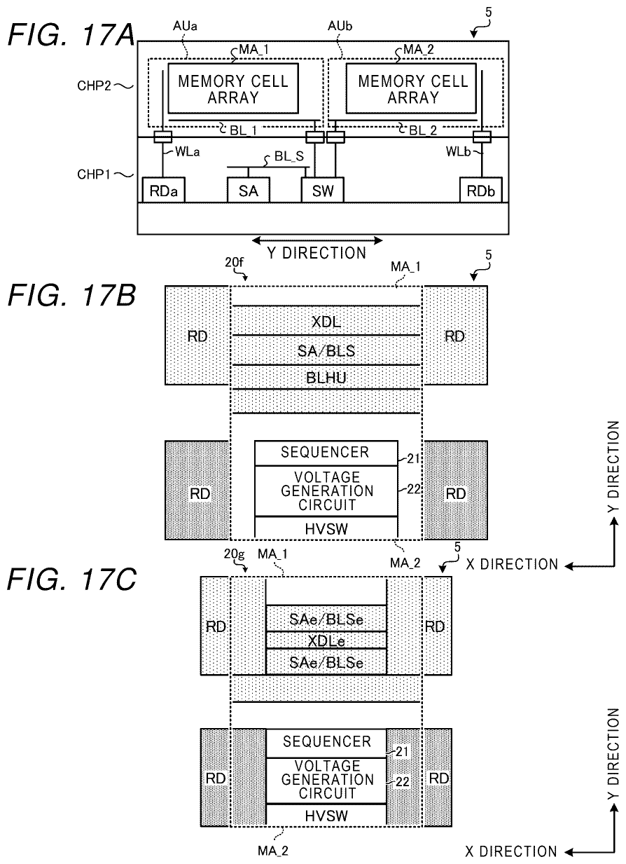

FIGS. 17A to 17C are diagrams showing an example of a configuration of a semiconductor memory device 5 according to Modification 4 of the embodiment. The semiconductor memory device 5 of Modification 4 differs from the above-described embodiment in that the semiconductor memory device 5 includes one array chip CHP2 for one circuit chip CHP1.

Among FIGS. 17A to 17C, FIG. 17A shows an example of the configuration of the semiconductor memory device 5, and FIGS. 17B and 17C show schematic layouts of peripheral circuits 20 f and 20g provided in the semiconductor memory device 5 according to Modification 4 of the embodiment.

As shown in FIG. 17A, the semiconductor memory device 5 of Modification 4 includes one circuit chip CHP1 and one array chip CHP2. The array chip CHP2 includes two memory cell arrays MA_1 and MA_2 aligned in the X direction. The circuit chip CHP1 includes the sense amplifier unit SA commonly connected to the memory cell arrays MA_1 and MA_2 via the switch circuit SW, and the row decoders RDa and RDb connected to the memory cell arrays MA_1 and MA_2 via the word line WL.

The memory cell array MA_1 is connected to the switch circuit SW by a bit line BL_1. The memory cell array MA_2 is connected to the switch circuit SW by a bit line BL_2. The switch circuit SW and the sense amplifier unit SA are connected via a sub-bit line BL_S.

Thus, each of the two memory cell arrays MA_1 and MA_2 forms a respective one of the array units AUa and AUb that are units of parallel processing.

As shown in FIG. 17B, a layout in which the plurality of sense amplifier units SA corresponding to the respective bit lines BL_1 and BL_2 are disposed across almost the entire region of the memory cell arrays MA_1 and MA_2 can also be applied to the semiconductor memory device 5 having such a configuration.

In the configuration of Modification 4, the sense amplifier unit SA is used in common for the two memory cell arrays MA_1 and MA_2, so the peripheral circuit 20f includes one set including the sense amplifier unit SA associated with the bit line selection circuit BLS, the bit line connection circuits BLHU, the latch circuit XDL, and the switch circuit SW. The widths of the components in the X direction are approximately equal to the widths of the memory cell arrays MA_1 and MA_2 in the X direction.

Meanwhile, the widths of the components in the Y direction is, for example, approximately half of the widths of the components shown in FIG. 16A above. Therefore, in the region corresponding to the memory cell arrays MA_1 and MA_2, the rest of components of the peripheral circuit 20f, such as the sequencer 21, the voltage generating circuit 22 (see FIG. 1 and the like), and the voltage selection circuit HVSW (see FIG. 4 and the like) can be disposed in the region in which the components are not disposed.

As shown in FIG. 17C, a layout in which the plurality of sense amplifier units SA corresponding to the respective bit lines BL_1 and BL_2 are concentrated near the center of the region corresponding to the memory cell arrays MA_1 and MA_2 in the X direction can be applied in the semiconductor memory device 5 provided with two memory cell arrays MA_1 and MA_2.

However, as described above, a stacked structure including the plurality of word lines WL and the like is formed by replacing sacrificial layers with word lines WL such as tungsten layers via slits that later become the plate-shaped portions ST in a structure in which a plurality of sacrificial layers NL are stacked.

In the above embodiment, the stacked structure including the sacrificial layers is separated for each memory cell array MA before a replacement process with the word lines WL and the like. However, it is also possible to perform the replacement process with the word lines WL and the like without separating the stacked structure for each memory cell array MA. Here, since no slit is disposed between two memory cell arrays MA, the replacement process with the word lines WL and the like may be insufficient, and the sacrificial layers may remain between the two memory cell arrays MA.

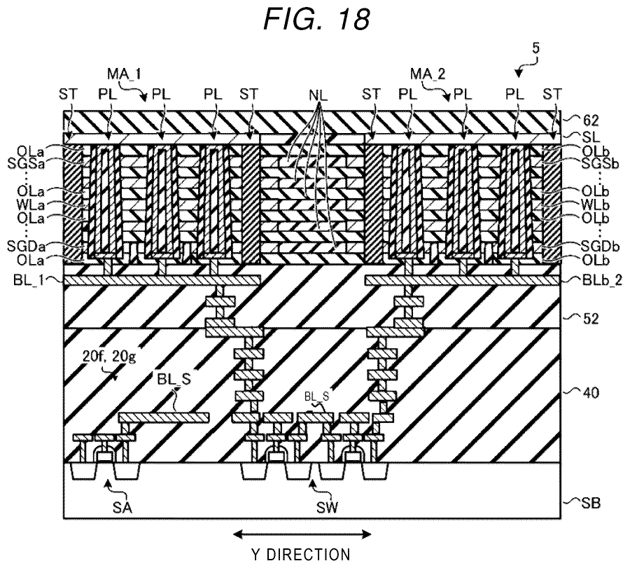

FIG. 18 is a cross-sectional view along the X direction showing an example of the configuration of the memory cell arrays MA_1 and MA_2 and the peripheral circuits 20f and 20g provided in the semiconductor memory device 5 according to Modification 4 of the embodiment. In the configuration shown in FIG. 18, a stacked structure including a sacrificial layer NL remains in a region between the two memory cell arrays MA_1 and MA_2. The sacrificial layer NL is an insulating layer such as a silicon nitride layer, so even when such a stacked structure remains between the memory cell arrays MA_1 and MA_2, electrical characteristics of the semiconductor memory device 5 are not affected.

Note that the structure in which the sacrificial layer NL remains can also be applied to a configuration including a plurality of array chips CHP2 and CHP3 as in the above-described embodiment, for example. Here, in at least one of the array chips CHP2 and CHP3, a structure can be implemented in which the sacrificial layer NL remains between the plurality of memory cell arrays MA in the array chips CHP2 and CHP3, respectively.

According to the semiconductor memory device 5 of Modification 4, by providing the switch circuit SW, the sense amplifier unit SA can be used in common for the two memory cell arrays MA_1 and MA_2.

According to the semiconductor memory device 5 of Modification 4, other effects similar to those of the above-described embodiment are achieved.

### Modification 5

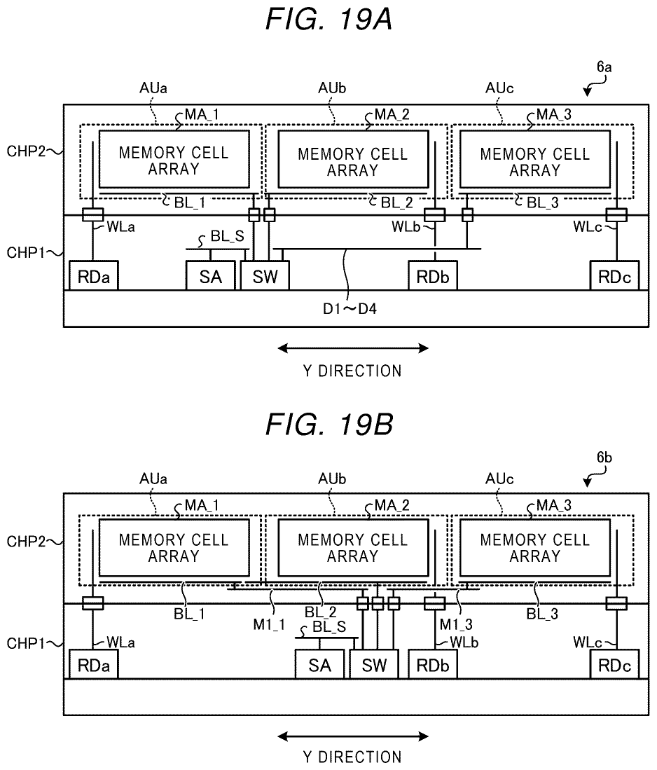

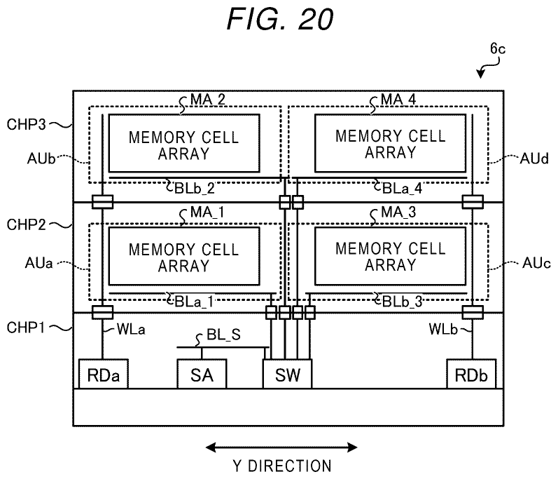

Regarding the above-described configuration of Modification 4, the number of memory cell arrays MA sharing the sense amplifier unit SA may be more than two. FIGS. 19A and 19B show an example in which three memory cell arrays MA share the sense amplifier unit SA. FIG. 20 shows an example in which four memory cell arrays MA share the sense amplifier unit SA.

FIGS. 19A to 20 are diagrams illustrating configurations of semiconductor memory devices 6a to 6c according to Modification 5 of the embodiment.

In the example shown in FIGS. 19A and 19B, the semiconductor memory devices 6a and 6b of Modification 5 have a configuration in which three memory cell arrays MA_1, MA_2, and MA_3 share the sense amplifier unit SA. The memory cell arrays MA_1, MA_2, and MA_3 are disposed sequentially in the Y direction, for example, and are connected to the switch circuit SW via bit lines BL_1, BL_2, and BL_3, respectively. The switch circuit SW and the sense amplifier unit SA are connected by the sub-bit line BL_S.

As shown in FIG. 19A, here, the sense amplifier unit SA can be disposed below any of the memory cell arrays MA_1, MA_2, and MA_3. The switch circuit SW can be disposed in a region between the memory cell array MA in which the sense amplifier unit SA is disposed and another memory cell array MA.

In the example of FIG. 19A, the sense amplifier unit SA is disposed below the memory cell array MA_1, and the switch circuit SW is disposed in a region between the memory cell arrays MA_1 and MA_2. Here, the memory cell arrays MA_1 and MA_2 can be connected to the switch circuit SW via the bit lines BL_1 and BL_2, respectively.

Meanwhile, for the memory cell array MA_3 separated from the switch circuit SW, the bit line BL_3 of the memory cell array MA_3 can be extended to a position overlapping the switch circuit SW in the vertical direction in any of the layers in which the wirings D1 to D4 of the circuit chip CHP1 are disposed, and can be connected to the switch circuit SW.

Alternatively, the connection path between the memory cell array MA_3 and the sense amplifier unit SA may intersect, for example, in the layer of the wiring M1_3 of the array chip CHP2, instead of in any layer of the circuit chip CHP1.

Row decoders RDa, RDb, and RDc are connected to the memory cell arrays MA_1, MA_2, and MA_3 via word lines WLa, WLb, and WLc, and the like, respectively.

In the above configuration, the three memory cell arrays MA_1, MA_2, and MA_3 each form array units AUa, AUb, and AUc that are units of parallel processing.

As shown in FIG. 19B, in a configuration including three memory cell arrays MA, the switch circuit SW may be disposed below any of the memory cell arrays MA_1, MA_2, and MA_3.

In the example of FIG. 19B, both the sense amplifier unit SA and the switch circuit SW are disposed below the memory cell array MA_2. Here, the memory cell array MA_2 can be connected to the switch circuit SW via the bit line BL_2.

Meanwhile, for the memory cell arrays MA_1 and MA_3 on both sides of the memory cell array MA_2 in the Y direction, the bit lines BL_1 and BL_3 of the memory cell arrays MA_1 and MA_3 can be extended to a position overlapping the switch circuit SW in the vertical direction, for example, in the layer of the wirings M1_1 and M1_3 of the array chip CHP2, and can be connected to the switch circuit SW.

Alternatively, connection paths between the memory cell arrays MA_1 and MA_3 and the sense amplifier unit SA may intersect not in the layer of the array chip CHP2, but in any layer in which the wirings D1 to D4 of the circuit chip CHP1 are disposed, for example.

In the example shown in FIG. 20, the semiconductor memory device 6c of Modification 5 has a configuration in which four memory cell arrays MA_1 to MA_4 share the sense amplifier unit SA. A stacked structure of the memory cell arrays MA_1 to MA_4 may be the same as that of the above-described embodiment, for example.

The sense amplifier unit SA can be disposed below the stacked structure of the memory cell arrays MA_1 and MA_2, or the memory cell arrays MA_3 and MA_4. The switch circuit SW can be disposed in a region between the stacked structures.

Here, the memory cell arrays MA_1, MA_2, and MA_3 can all be connected to the switch circuit SW via bit lines BL_1, BL_2, BL_3, and BL_4, respectively.

In the above configuration, the four memory cell arrays MA_1, MA_2, MA_3, and MA_4 each form a respective one of array units AUa, AUb, AUc, and AUd that are units of parallel processing.

According to the semiconductor memory device 6c of Modification 5, by providing the switch circuit SW, the sense amplifier unit SA can be used in common for the four memory cell arrays MA.

According to the semiconductor memory devices 6a to 6c of Modification 5, other effects similar to those of the above-described embodiment are achieved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first memory cell array including a plurality of first memory cells;
a second memory cell array including a plurality of second memory cells;
a first sense amplifier unit by which data is read from the plurality of first and second memory cells; and
a first switch circuit that is configured to switch between electrically connecting the plurality of first memory cells to the first sense amplifier unit, and electrically connecting the plurality of second memory cells to the first sense amplifier unit, wherein
the first memory cell array and the first sense amplifier unit are arranged to overlap each other when viewed in a vertical direction,
the second memory cell array is arranged at a position shifted in a horizontal direction with respect to the first memory cell array and the first sense amplifier unit, and
the first switch circuit is arranged at a position overlapping a region between the first and second memory cell arrays when viewed in the vertical direction or a position overlapping the first memory cell array when viewed in the vertical direction.

2. The semiconductor memory device according to claim 1, wherein
the first switch circuit is arranged at a position overlapping the region between the first and second memory cell arrays when viewed in the vertical direction.

3. The semiconductor memory device according to claim 1, further comprising:
a plurality of bit lines spaced apart from each other in a first direction along a first surface of the first memory cell array facing the first sense amplifier unit on a side of the first memory cell array facing the first sense amplifier unit, extending in a second direction intersecting the first direction along the first surface, and connected to the plurality of first memory cells; and
a plurality of sub-bit lines spaced apart from each other in the first direction and extending in the second direction at positions overlapping the plurality of bit lines when viewed in in the vertical direction on a side of the first sense amplifier unit facing the first memory cell array and connected to the first sense amplifier unit.

4. The semiconductor memory device according to claim 3, wherein
the plurality of bit lines are at a first height that is between the first memory cell array and the first sense amplifier unit, and
the plurality of sub-bit lines are at a second height that is between the first memory cell array and the first sense amplifier unit and closer to the first sense amplifier unit than the first height.

5. The semiconductor memory device according to claim 3, wherein
the plurality of bit lines are at a first height that is between the first memory cell array and the first sense amplifier unit,
a first part of the plurality of sub-bit lines are at a second height that is between the plurality of bit lines and the first sense amplifier unit and closer to the first sense amplifier unit than the first height, and
a second part of the plurality of sub-bit lines are at a third height that is between the plurality of bit lines and the first sense amplifier unit and closer to the first sense amplifier unit than the second height.

6. The semiconductor memory device according to claim 3, further comprising:
an interface provided between the first and second memory cell arrays and the first sense amplifier unit and including a bonding pad, wherein
the plurality of sub-bit lines are between the first sense amplifier unit and the interface.

7. The semiconductor memory device according to claim 3, further comprising:
an interface provided between the first and second memory cell arrays and the first sense amplifier unit and including a bonding pad, wherein
the plurality of sub-bit lines are between the first memory cell array and the interface.

8. The semiconductor memory device according to claim 1, further comprising:
a third memory cell array including a plurality of third memory cells, wherein the first to third memory cell arrays are arranged sequentially in the horizontal direction,
data from the plurality of third memory cells is also read by the first sense amplifier unit, and
the first switch circuit is configured to selectively electrically connect one of the plurality of first memory cells, the plurality of second memory cells, and the plurality of third memory cells to the first sense amplifier unit.

9. The semiconductor memory device according to claim 8, wherein
the first switch circuit is disposed at a position overlapping the first memory cell array when viewed in the vertical direction.

10. The semiconductor memory device according to claim 1, further comprising:
a third memory cell array including a plurality of third memory cells; and
a fourth memory cell array including a plurality of fourth memory cells, wherein
the third memory cell array is arranged to overlap the second memory cell array when viewed in the vertical direction,
the fourth memory cell array is arranged to overlap the first memory cell array and the first sense amplifier unit when viewed in the vertical direction,
data from the plurality of third and fourth memory cells is also read by the first sense amplifier unit, and
the first switch circuit is configured to selectively electrically connect one of the plurality of first memory cells, the plurality of second memory cells, the plurality of third memory cells, and the plurality of fourth memory cells to the first sense amplifier unit.

11. The semiconductor memory device according to claim 10, wherein
the first and third memory cell arrays are arranged side by side in the horizontal direction, and
the second and fourth memory cell arrays are arranged side by side in the horizontal direction.

12. The semiconductor memory device according to claim 1, further comprising:
a third memory cell array including a plurality of third memory cells; and
a fourth memory cell array including a plurality of fourth memory cells;
a second sense amplifier unit by which data is read from the third and fourth memory cells; and
a second switch circuit that is configured to switch between electrically connecting the plurality of third memory cells and the second sense amplifier unit, and electrically connecting the plurality of fourth memory cells to the second sense amplifier unit, wherein
the second memory cell array, the third memory cell array, and the second sense amplifier unit are arranged to overlap each other when viewed in the vertical direction,
the fourth memory cell array is arranged to overlap the first memory cell array and the first sense amplifier unit when viewed in the vertical direction,
the second switch circuit is arranged at a position overlapping a region between the plurality of first and second memory cell arrays when viewed in the vertical direction and closer to the second sense amplifier unit than the first switch circuit.

13. The semiconductor memory device according to claim 12, wherein
the first and third memory cell arrays are disposed side by side in the horizontal direction, and
the second and fourth memory cell arrays are disposed side by side in the horizontal direction.

14. The semiconductor memory device according to claim 13, further comprising:
a plurality of first bit lines spaced apart from each other in a first direction along a first surface of the first memory cell array facing the first sense amplifier unit on a side of the first memory cell array facing the first sense amplifier unit, extending in a second direction intersecting the first direction along the first surface, and connected to the plurality of first memory cells;
a plurality of second bit lines extending in the second direction at the same height as the plurality of first bit lines on a side of the third memory cell array facing the second sense amplifier unit at positions overlapping each of the plurality of first bit lines when viewed in the second direction and connected to each of the plurality of third memory cells;
a plurality of first relay wirings extending in the second direction at the same height as the plurality of first bit lines between the first and second memory cell arrays at positions overlapping each of the plurality of first bit lines when viewed in the second direction and connected to the first switch circuit; and
a plurality of second relay wirings extending in the second direction at the same height as the plurality of first bit lines between the first and second memory cell arrays at positions overlapping each of the plurality of first bit lines when viewed in the second direction and connected to the second switch circuit, wherein
the plurality of second memory cells are connected to the first switch circuit via the plurality of first relay wirings, and
the plurality of fourth memory cells are connected to the second switch circuit via the plurality of second relay wirings.

15. The semiconductor memory device according to claim 14, further comprising:
a plurality of third bit lines extending in the second direction at positions overlapping the plurality of first bit lines when viewed in the vertical direction on a side of the fourth memory cell array facing the first memory cell array and connected to each of the plurality of fourth memory cells; and
a plurality of fourth bit lines extending when viewed in the second direction at positions overlapping each of the plurality of third bit lines when viewed in the first direction on a side of the second memory cell array facing the third memory cell array at the same height as the plurality of third bit lines and connected to each of the plurality of third memory cells, wherein
the plurality of third bit lines are each connected to one of the plurality of second relay wirings via a first plug extending in the vertical direction, and
the plurality of fourth bit lines are each connected to one of the plurality of first relay wirings via a second plug extending in the vertical direction.

16. The semiconductor memory device according to claim 15, wherein
the plurality of first bit lines, the plurality of first relay wirings, the plurality of second relay wirings, and the plurality of second bit lines are disposed side by side sequentially in the second direction.

17. The semiconductor memory device according to claim 15, wherein
the plurality of first bit lines, the plurality of second relay wirings, the plurality of first relay wirings, and the plurality of second bit lines are disposed side by side sequentially in the second direction, and
at least a part of the fourth bit lines extend from positions overlapping the second memory cell array when viewed in the vertical direction to positions overlapping the plurality of first relay wirings when viewed in the vertical direction and are connected to each of the plurality of first relay wirings.

18. The semiconductor memory device according to claim 12, wherein
the first and second memory cell arrays are disposed side by side in the horizontal direction, and
the third and fourth memory cell arrays are disposed side by side in the horizontal direction.

19. A semiconductor memory device comprising:
a first memory cell array including a plurality of first memory cells;
a second memory cell array including a plurality of second memory cells;
a third memory cell array including a plurality of third memory cells; and
a fourth memory cell array including a plurality of fourth memory cells;
a first sense amplifier unit by which data is read from the first and second memory cells;
a second sense amplifier unit by which data is read from the third and fourth memory cells;
a first switch circuit that is configured to switch between electrically connecting the plurality of first memory cells to the first sense amplifier unit, and electrically connecting the plurality of second memory cells to the first sense amplifier unit; and
a second switch circuit that is configured to switch between electrically connecting the plurality of third memory cells to the second sense amplifier unit, and electrically connecting the plurality of fourth memory cells to the second sense amplifier unit, wherein
the first and fourth memory cell arrays and the first sense amplifier unit are arranged to overlap each other when viewed in a vertical direction,
the second and third memory cell arrays and the second sense amplifier unit are arranged to overlap each other when viewed in the vertical direction at a position shifted in a horizontal direction with respect to the first and fourth memory cell arrays and the first sense amplifier unit, and
the first and second switch circuits are arranged at a position overlapping a region between the first and fourth memory cell arrays and the second and third memory cell arrays when viewed in the vertical direction.

20. A semiconductor memory device comprising:
a first semiconductor chip comprising the first and second switch circuits of claim 19;
a second semiconductor chip bonded to the first semiconductor chip above the first semiconductor chip, said second semiconductor chip comprising the first and third memory cell arrays of claim 19; and
a third semiconductor chip bonded to the second semiconductor chip above the second semiconductor chip, said third semiconductor chip comprising the second and fourth memory cell arrays of claim 19.
